(19) United States
(12) Patent Application Publication
(10) Pub. No.: US 2009/0115435 A1
(43) Pub. Date: May 7, 2009

(54) Processing System and Method for Hand-Held Impedance Spectroscopy Analysis Device for Determining Biofuel Properties

(76) Inventor: Douglas F. Tomlinson, Waunakee, WI (US)

Correspondence Address: WHYTE HIRSCHBOECK DUDEK S.C.;INTELLECTUAL PROPERTY DEPARTMENT, 33 East Main Street, Suite 300, Madison, WI, 53703-4655, US

(21) Appl. No.: 12/262,925

(22) Filed: Oct. 31, 2008

Related U.S. Application Data
(60) Provisional application No. 60/985,120, filed on Nov. 2, 2007.
(60) Provisional application No. 60/985,127, filed on Nov. 2, 2007.
(60) Provisional application No. 60/985,134, filed on Nov. 2, 2007.

(51) Int. Cl. G01R 27/08; G01N 31/00

(52) U.S. Cl. 324/698; 702/25

(57) ABSTRACT

Disclosed herein is a hand-held impedance spectroscopy analysis device for analyzing fluids wherein the impedance spectroscopy device is in communication with a sample cell including a reservoir containing a fluid sample, the sample cell including a sample cell circuit and two metal plates in contact with the fluid sample and in contact with a pair of electrodes. The analysis device includes a processing system including a main processor which is responsive to commands from a user input device, and a data acquisition circuit which receives power and command signals from the processing system. The data acquisition circuit is operable to transmit excitation signals to the electrodes, wherein the excitation signals are applied at each frequency in a predetermnined set of frequencies, and the data acquisition circuit is further operable to receive response signals from the electrodes indicative of the fluid sample at each frequency in the predetermined set of frequencies and to convert the response signals into a magnitude and phase angle data set. The main processor is operable to receive the magnitude and phase angle data set from the data acquisition circuit and to receive at least one of calibration information and temperature information from the sample cell circuit and perform an impedance spectroscopy algorithm using the magnitude and phase angle data set and the information from the sample cell circuit to determine a fluid property.

### CROSS-REFERENCE TO RELATED APPLICATIONS

This application claims priority to U.S. provisional patent application Ser. Nos. 60/985,120; 60/985,127, and 60/985,134, all filed on Nov. 2, 2007.

### FIELD OF THE INVENTION

The present invention relates to systems and methods for analyzing fluids. More particularly the present invention relates to systems and methods that employ impedance spectroscopy (IS) for analyzing fluids.

### BACKGROUND OF TIE INVENTION

Increasing consumption of fossil fuels is occurring on a worldwide basis. Many countries rely on fossil fuel use to the detriment of society and ecosystems. Reduction in the amount of fossil fuel consumption and increased use of bio-based fuels has become an increasingly important initiative for consumers and governments alike. In particular, the increased use of biodiesel is lauded as an important step in the direction of reducing fossil fuel consumption and usage. However, the transition for including biodiesel in everyday fuel has created a series of problems to both diesel consumers and combustion engine manufacturers. A key problem surrounds determining the concentration of biofuel, often referred to as fatty acid methyl ester (FAME), within a biodiesel sample. Identification of other alkyl esters is contemplated by this invention.

Biodiesel is often defined as the monoalkyl esters of fatty acids from vegetable oils and animal fats. Neat and blended with conventional petroleum diesel fuel, biodiesel has seen significant use as an alternative diesel fuel. Biodiesel is often obtained from the neat vegetable oil transesterification with an alcohol, usually methanol (other short carbon atom chain alcohols may be used), in the presence if a catalyst, often a base. Various unwanted materials are found in biodiesel, which can include glycerol, residual alcohol, moisture, unreacted feedstock (triglycerides), monoglycerides, diglycerides, and free (unreacted) fatty acids.

Biodiesel fuels are often blended compositions of diesel fuel and biomass, which is often esterified soy-bean oils, rapeseed oils or various other vegetable oils. It is the similar physical and combustible properties to diesel fuel that has allowed the development of biofuels as an energy source for combustion engines. However, biofuels are not a perfect replacement for diesel. By example, the cetane number, oxidation stability and corrosion potential of these biofuels present a concern to continued consumption as a viable fuel. Based upon these issues, as well as others known to one skilled in the art, careful control of the biofuel properties must be implemented.

Beyond the physical and chemical concerns, monetary concerns exist. The United States government provides a tax credit for biofuel consumption. The tax credit is based upon the biofuel percentage within a biodiesel blend. In fact, the tax credit can be substantially different for a slight change in the percentage, since $0.01 per FAME percentage per gallon used is provided by the government. Therefore the difference between 20% and 25% FAME in biodiesel fuel can result in a considerable tax value. Often it is the case that biodiesel blends are “splash-blended”, which refers to the liquid agitation that occurs as the fuel truck is driving on the road after the diesel and biofuel have been combined. “Splash-blended” biodiesel blends often have a blend variance of up to 5%, which is unacceptable.

Various methods and technologies have been employed to determine the biofuel percentage within a biodiesel blend. These methods include gas chromatography (GC), fourier transform infrared (FTIR) spectroscopy, and near-infrared (NIR) spectroscopy. None of these methods provide a portable, quick and accurate determination of the FAME percentage within a biodiesel blend.

It would be advantageous to have a system and method for quickly and accurately determining the concentration of biodiesel fuel blends for use in quality control, production testing and distribution testing.

### BRIEF DESCRIPTION OF THE DRAWINGS

FIG. 1 is a block diagram of the fuel analyzer system in accordance with at least one embodiment of the invention.

FIG. 2 is a block diagram of a logic controller in accordance with at least one embodiment of the invention.

FIG. 3 is an alternative embodiment of the fuel analyzer system in accordance with at least one embodiment of the invention.

FIG. 4 is a flow chart representing a method for analyzing biodiesel blends in accordance with at least one embodiment of the invention.

FIG. 5 is a FTIR spectra for biodiesel concentration.

FIG. 6 is a Beer's Law FTIR model for biodiesel concentration standards.

FIG. 7 is a room temperature impedance spectra for biodiesel standards.

FIG. 8 is an impedance spectroscopy model for biodiesel concentration standards.

FIG. 9 is a test data table including both FTIR and impedance spectroscopy data.

FIG. 10 is a biodiesel method comparison data plot.

FIG. 11 is a biodiesel method residuals data plot.

FIG. 12 is an alternative embodiment of the impedance spectroscopy data analyzer in accordance with at least one embodiment of the present invention.

FIG. 13 is a measured form calculation sequence.

FIG. 14 is a complex Plane Representation mathematical sequence.

FIG. 15 is an impedance and modulus plot sequence.

FIG. 16 is a biodiesel modulus spectra plot.

FIG. 17 is an impedance spectroscopy derived model data plot.

FIG. 18 is an exemplary block and wiring diagram for one embodiment of a device of this invention, the block and wiring diagram having a main board and a data acquisition board (DAQ).

FIG. 19 is a partially exploded front perspective view of the exemplary hand-held analyzer device illustrated in block diagram form in FIG. 18, in accordance with at least some embodiments of the invention;

FIG. 19A is a perspective view of an exemplary sample cell for use in conjunction with the hand-held analyzer device of FIG. 19, in accordance with at least some embodiments of the present invention;

FIG. 20 is another partially exploded front perspective view of the hand-held analyzer device of FIG. 19.

FIG. 21 is an exemplary circuit diagram of the main board of the block and wiring diagram of FIG. 18, in accordance with at least some embodiments of the present invention.

FIG. 22 is an exemplary circuit diagram of a power section of the main board of FIG. 21, in accordance with at least some embodiments of the present invention.

FIG. 23 is an exemplary circuit diagram of the DAQ of the block and wiring diagram of FIG. 18, the DAQ circuit having a signal generator block and a transimpedance and power amplifier (TPA) block in accordance with at least some embodiments of the present invention.

FIG. 24 is an exemplary circuit diagram of the signal generator block of the DAQ circuit of FIG. 21, in accordance with at least some embodiments of the present invention.

FIG. 25 is an exemplary circuit diagram of the TPA block of the DAQ circuit of FIG. 21, in accordance with at least some embodiments of the present invention. And

FIG. 26 is an exemplary circuit diagram of a transimpedance amplifier (TIA) block of the circuit of the TPA block of FIG. 25, in accordance with at least some embodiments of the present invention.

### DETAILED DESCRIPTION OF THE PREFERRED EMBODIMENT

Biodiesel includes fuels comprised of short chain, mono-alkyl, preferably methyl, esters of long chain fatty acids derived from vegetable oils or animal fats. Short carbon atom chain alkyl esters have from e.g., 1 to 6 carbon atoms, preferably 1 to 4 carbon atoms and most preferably 1 to 3 carbon atoms. Biodiesel is also identified as B100, the “100” representing that 100% of the content is biodiesel. Biodiesel blends include a combination of both petroleum-based diesel fuel and biodiesel fuel. Typical biodiesel blends include B5 and B20, which are 5% and 20% biodiesel respectively. Diesel fuel is often defined as a middle petroleum distillate fuel.

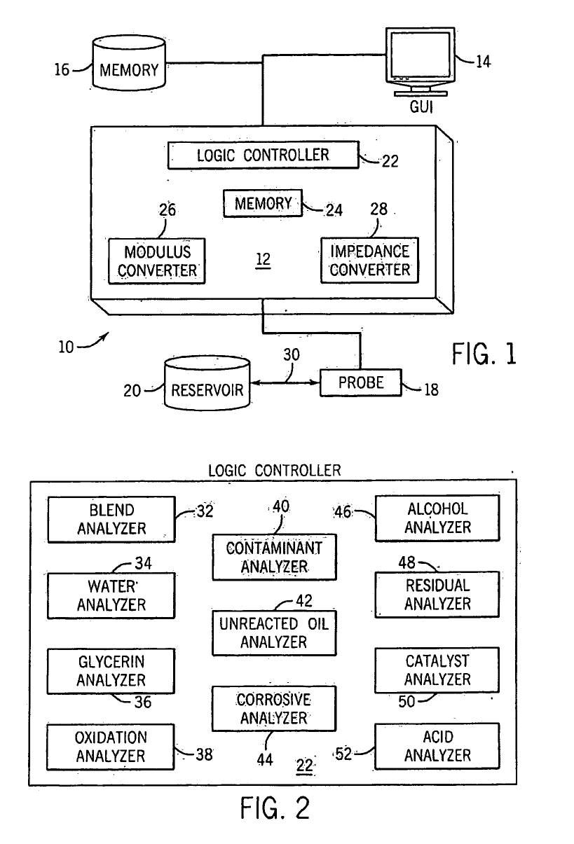

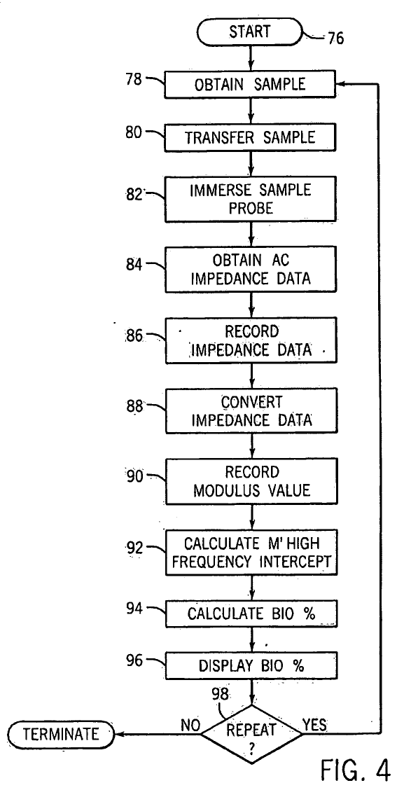

Now referring to FIG. 1, an illustrative example of the system 10 in accordance with at least one embodiment of the invention includes an analysis device 12, graphical user interface (GUI) 14, memory storage device 16, probe 18, and reservoir 20. The analysis device 12 includes a logic controller 22, a memory storage device 24, a modulus converter 26 and an impedance converter 28. The reservoir 20 contains a biofuel sample, which can be selected from the group including a biodiesel blend, heating fuel, second phase materials, fuel additives, methanol, glycerol, residual alcohol, moisture, unreacted feedstock (triglycerides), monoglycerides, diglycerides, and free (unreacted) fatty acids. The probe 18 is external and separately connected to the reservoir 20 and can alternatively be integrated within the reservoir 20. The probe 18 provides inputs to the reservoir 20 through input/output line 30. Excitation voltage (V_{(f)} is applied to the reservoir from probe 18 and a response current (I_{(f)} over a range of frequencies is measured and provided to the analysis device 12. The impedance data is analyzed and converted by the impedance converter 28, and then transferred to the modulus converter 26. The impedance data includes Zᵣₑₐₗ, Z_{imaginary}and frequency. The modulus data includes Mᵣₑₐₗ, M_{imaginary}, and frequency. The logic controller 22 operates the modulus converter 26 and impedance converter 28 to store the respective data, including the impedance measurements, within memory storage device 24. The logic controller performs a computer readable function, which is accessed from memory storage device 24 that performs an impedance spectroscopy analysis method (See FIG. 4) and provides a biodiesel concentration to the GUI 14. The concentration data can be provided in the form of Bxx, where “xx” represents the concentration of the sample tested that is biofuel (biomass/FAME) in percentage of biodiesel. Concentration and percentage are often used interchangeably to describe the amount of biodiesel within a blended sample.

Referring to FIG. 2, an alternative embodiment of the logic controller 22 is illustrated. The logic controller 22 includes a blend concentration analyzer 32, a water analyzer 34, a glycerin analyzer 36, an oxidation analyzer 38, a contaminant analyzer 40, and unreacted oil analyzer 42, a corrosive analyzer 44, an alcohol analyzer 46, a residual process chemistry analyzer 48, a catalyst analyzer 50, and a total acid number analyzer 52. The water analyzer 34 performs analysis on the impedance data obtained from probe 18. The logic controller 22 accesses a computer readable function accessed from memory storage device 24 and provides information such as the presence of water, and if identified within the sample, the concentration of water within the sample. The glycerin analyzer 36 performs analysis on the impedance data obtained from probe 18. The logic controller 22 accesses a computer readable function accessed from memory storage device 24 and provides information such as the presence of glycerin, and if identified within the sample, the concentration of glycerin within the sample. Alternatively, the computer readable function is accessed from memory 16. In an alternative embodiment, a viscosity analyzer (not shown), and cetane number analyzer (not shown) are included for providing viscosity data and cetane number data for a fuel sample. In yet another alternative embodiment, a sludge/wax analyzer (not shown) are included for providing information on the presence and amount of sludge and/or wax precipitation within a fuel sample.

The oxidation analyzer 38 performs analysis on the impedance data obtained from probe 18. The logic controller 22 accesses a computer readable function accessed from memory storage device 24 and provides information such as the presence of oxidation. The contaminant analyzer 40 performs analysis on the impedance data obtained from probe 18. The logic controller 22 accesses a computer readable function accessed from memory storage device 24 and provides information such as the presence of contaminants, and identification of the type of contaminants within the sample, as well as the concentration of the particular contaminant within the sample. A variety of contaminants can be found within fuel samples, which include water, wax/sludge, and residual process chemistry.

The unreacted oil analyzer 42 performs analysis on the impedance data obtained from probe 18. The logic controller 22 accesses a computer readable function from memory storage device 24 and provides information such as the presence of unreacted oils, as well as the concentration within the sample. A variety of unreacted oil can be found within fuel samples, which include unreacted feedstock (triglycerides), monoglycerides, diglycerides, and free (unreacted) fatty acids.

The corrosive analyzer 44 performs analysis on the impedance data obtained from probe 18. The logic controller 22 accesses a computer readable function from memory storage device 24 and provides information such as the presence of corrosives, as well as the reactivity of the corrosive substances within the sample.

The alcohol analyzer 46 performs analysis on the impedance data obtained from probe 18. The logic controller 22 accesses a computer readable function from memory storage device 24 and provides information such as the presence of alcohol, and if present, the concentration of alcohol within the sample. The residual analyzer 48 performs analysis on the impedance data obtained from probe 18. The logic controller 22 accesses a computer readable function memory storage device 24 and provides information such as the presence of residuals, and identification of the type of residuals within the sample, as well as the concentration of the residuals within the sample. A variety of residuals can be found within fuel samples, which include alcohol, catalyst, glycerin and unreacted oil.

The catalyst analyzer 50 performs analysis on the impedance data obtained from probe 18. The logic controller 22 accesses a computer readable function from memory storage device 24 and provides information such as the presence of catalysts, as well as the concentration of the catalysts within the sample. A variety of catalysts can be found within fuel samples, which include KOH and NaOH. The total acid number analyzer 52 performs analysis on the impedance data obtained from probe 18. The logic controller 22 accesses a computer readable function from memory storage device 24 and provides information such as the presence of acids, as well as the concentration of the acids within the sample. A variety of acids can be found within fuel samples, which include carboxylic acid and sulfuric acid.

In an alternative embodiment, a stability analyzer (not shown) is provided. The stability analyzer performs analysis on the impedance data obtained from probe 18. The logic controller 22 accesses a computer readable function accessed from memory storage device 24 and provides information such as a stability value. Recent research has found that changes to the biodiesel element of biodiesel blends can have a deleterious effect upon the stability of the fuel sample over time. Blended samples that are left inactive for extended periods of time can potentially lose stability. The impedance spectroscopy data and stability analyzer function of this invention can provide information as to the sample's stability and efficacy.

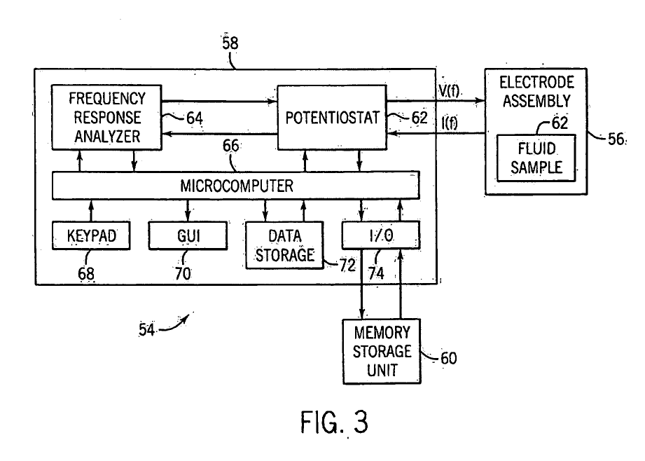

Referring to FIG. 3, an alternative embodiment of the impedance spectroscopy analyzing system 54, which includes an electrode assembly 56, a data analyzer 58, and a memory storage unit 60 is provided. The electrode assembly 56 includes a fluid sample 62 and probes (not shown). The data analyzer 58 includes a potentiostat 63, a frequency response analyzer 64, a microcomputer 66, a keypad 68, a GUI (graphical user interface) 70, data storage device 72, and I/O device 74. Impedance data is obtained from the electrode assembly 56 and input into the analyzer 58. The potentiostat 63 and frequency response analyzer together perform the impedance spectroscopy analysis methods (See FIG. 4). The microcomputer 66 accesses the computer readable functions from the memory storage unit 60 or the data storage device 72, and provide biofuel analyzed data to the GUI 70

Referring to FIG. 4, a flow chart is provided representing a method for determining the concentration of biodiesel (e.g., biomass/FAME content) in a blended biodiesel fuel sample in accordance with at least one embodiment of the present invention. The system 10 is initiated at step 76. A sample of the blended biodiesel is obtained at step 78 and then transferred to a clean container or reservoir at step 80. The sample is maintained at substantially room temperature, generally between about 60° F. and about 85° F. Alternatively, the sample is located in a vehicle fuel tank on board a vehicle or deployed “in-line” e.g., in a biodiesel synthesis plant.

Measurement probes are cleaned and immersed within the reservoir at step 82. Alternatively, probes can be maintained within the reservoir and the fuel sample is added to the reservoir with the probes already within the reservoir. The probes can be self-cleaning probes. The impedance device is initiated and the AC impedance characteristics of the fuel sample are obtained at step 84. The frequency range extends from about 10 milliHertz to about 100 kHertz, or alternatively appropriate frequencies. The impedance data is recorded at step 86. The data can be saved in a memory device integral to the device 12. Alternatively, the impedance data is saved in an external memory device. The external memory device 16 can be a relational database or a computer memory module. At step 88, the impedance data is converted to complex modulus values. The complex modulus values are recorded at step 90. M′ high frequency intercept values are determined at step 92 from the complex modulus values and the biodiesel concentration is calculated at step 94. By example, Equation Set 1 is a linear algorithm used for calculating the biodiesel blend concentration. The biodiesel concentration value is represented on a user interface at step 96. If the process continues step 78 is repeated at 98, otherwise the sequence is terminated at step 100. One skilled in the art would recognize that there are chemical differences between biodiesel and petroleum-based diesel for which the present invention can be employed.

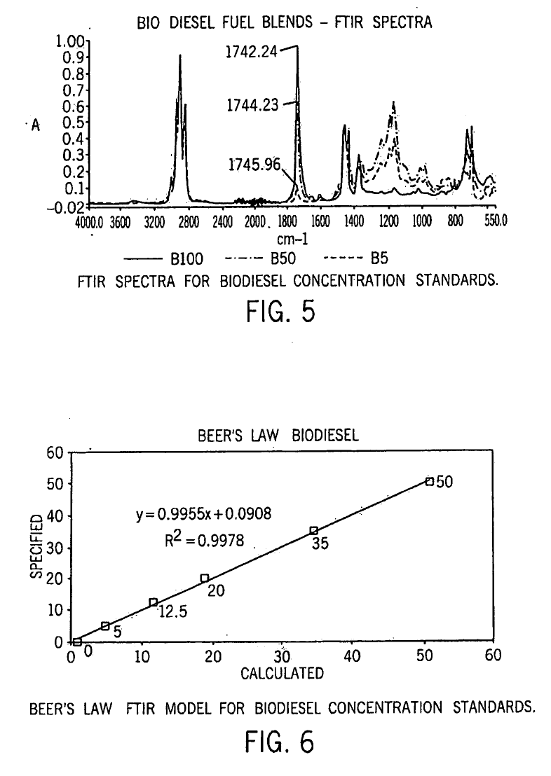

The Fourier transform infrared (FTIR) spectra analysis of three biodiesel concentration is provided in FIG. 5. Samples of B100, B50, and B5 were tested using an FTIR process. The FTIR process used for data obtained in FIG. 5 was modeled after the AFNOR NF EN 14078 (July 2004) method, titled “Liquid petroleum products—Determination of fatty acid methyl esters (FAME) in middle distillates—Infrared spectroscopy method.” Biodiesel fuel samples were diluted in cyclohexane to a final analysis concentration of about 0% to about 1.14% biofuel. This was to produce a carbonyl peak intensity that ranged between about 0.1 to about 1.1 Abs, using a 0.5 mm cell pathlength. The method showed a 44 g/l sample (B5 sample was diluted to 0.5%) having 0.5 Abs carbonyl peak height. The method recommended 5-standards be prepared ranging from about 1 g/l (about 0.11% biofuel) to about 10 g/l (about 1.14% biofuel).

The peak height of the carbonyl peak at or near 1245 cm⁻¹ was measured to a baseline drawn between about 1820 cm⁻¹ to about 1670 cm⁻². This peak height was used with a Beer's Law plot of absorbance versus concentration to develop a calibration curve for unknown calculation.

The modifications made to this method included no sample dilution, an ATR cell and utilization of peak area calculations. Sample dilution with cyclohexane is a very large source of errors. The reasons to dilute the sample include reducing the viscosity for flow (transmission cell), opacity or to maintain the absorption peak height of the sample with the detector linearity. The detector linearity of the instrument used was in the range of about 0 Abs to about 2.0 Abs. By reducing the cell pathlength to about 0.018 mm the absorbance of a B100 sample was about 1.0 Abs. This allowed dilution to be unnecessary. The use of a UATR cell allowed a very controlled and fixed pathlength to be maintained.

The peak of interest demonstrated migration during dilution due to solvent interaction, evidenced in the biofuel spectra shown in FIG. 5. As a result, the peak area was chosen as the measurement technique. In addition, peak area is the preferred technique for samples that contain multiple types of a defined chemistry type, such as that found in biofuels. Substances found in biofuels that are distinguishable from one another and from petroleum-based fuels constituents by means of impedance spectroscopy are, of course, a focus of this invention. Exemplary substances include saturated and unsaturated esters. The result of Beer's Law calibration is shown in FIG. 6. The biofuel samples were measured against the calibration curve of FIG. 6. The impedance spectroscopy methods were measured against this FTIR process.

Equation Set 1:

y=−3.371E+07x+8.158E+09,

where y=M′ and x=% biodiesel

At least one embodiment of the present invention was tested for feasibility by comparison with FTIR analysis, an industry accepted test method, of biodiesel fuel blend concentration. The blend samples that were tested included B50, B20 and B5. The samples were evaluated using both broad spectrum AC impedance spectroscopy as well as FTIR spectroscopy. Additionally, the blends of unknown values were tested to determine the impedance data using impedance spectroscopy. Conventional diesel fuel and a variety of nominal blend ratios were used as test standards.

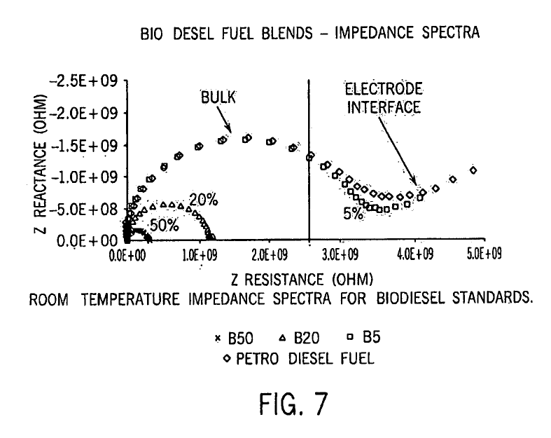

Approximately 20 mL samples of each biodiesel blend were evaluated at room temperature utilizing a two (2) probe measurement configuration. FIG. 7 provides an example of the impedance spectra in a line plot configuration, with reactance (ohm) plotted against resistance (ohm). The impedance spectra provide a clear distinction between B50, B20, B5, and petroleum diesel fuel. Generally the impedance at given frequency, ω, contains two contributions as shown in Equation Set 2. More specifically, FIG. 7 provides the resistance (Rₛ) plotted against the Reactance (1/ωCₛ), which provides an indication that the resistivity of the biodiesel blend sample is sensitive to the percent biodiesel within the base diesel fuel. As a result, the impedance spectra can be used to identify the concentration percentage of biodiesel within a biodiesel blend sample.

Equation Set 2:

Z*(ω)=Rₛ−j(1/ωCₛ)

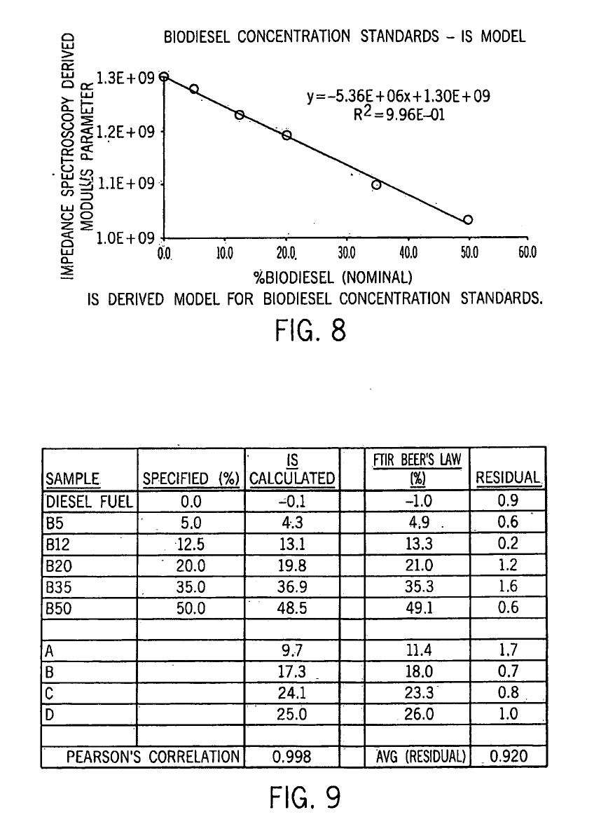

Further manipulation of the impedance data indicates that the polarizability of the blended biodiesel sample is systematically impacted as the concentration of biodiesel increases or decreases. Therefore, a real modulus representation value can be calculated. This presents a parameter, for which a correlation can be made. A correlation between the measured impedance-derived spectra data and the stated biodiesel percentage concentration value can be established. The correlation is graphically presented in FIG. 8, where the impedance derived modulus parameter is plotted against the biodiesel concentration. A linear relationship having a negative slope is provided. These results provide an indication that a correlation similar to that of the industry accepted FTIR method is feasible for impedance spectroscopy.

Referring to FIG. 9, a test data table is provided. The table includes known biodiesel standards, including pure petroleum diesel fuel, B5, B12, B20, B35, and B50. Each of these standards (Reference Standards) was tested using the FTIR process and the impedance spectroscopy process of the present embodiment. The results for each of these tests are provided in the table. Additionally there are four unknowns, A, B, C, and D (Unknown Blend Set 1), for which test results were obtained using both the FTIR process and the impedance spectroscopy process of the present embodiment.

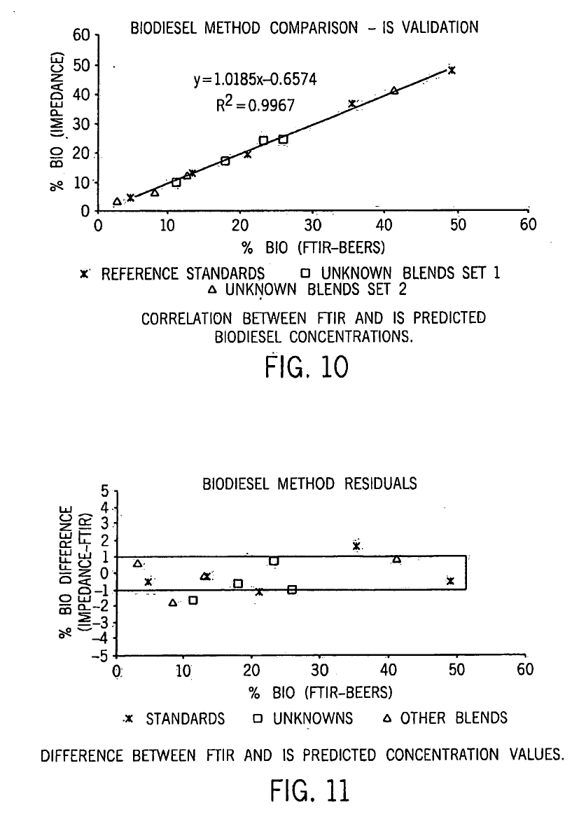

Referring to FIG. 10, the test data provided in FIG. 9 is presented in the form of a X-Y plot. The biodiesel concentration data obtained from the impedance spectroscopy process is plotted against the biodiesel concentration data obtained from the FTIR process. A correlation line is fit to the data points, which indicates a close correlation between the two methods for determining biodiesel concentration. Additionally, a second set of unknown biodiesel blends (Unknown Blends Set 2) were tested through both stated processes. These unknown blends were prepared by blending B100 and two separate petroleum fuels. These data points are not provided in FIG. 9, but are plotted in FIG. 10.

A scientifically significant agreement between the FTIR process and the impedance spectroscopy process of the present embodiment was found. This is evidenced by the line fit assigned to the plotted data points. Residual values (% bio_{FTIR}−% bio_{impedance}) were calculated and provided in FIG. 9. The average residual value is 0.920, which is less than 1.0%, presenting a highly significant linear correlation between the widely accepted FTIR process and the impedance spectroscopy process of the present embodiment. The difference between the FTIR process and the impedance spectroscopy process of the present embodiment are presented in FIG. 11.

The system 10 can be implemented in the form of a low cost, portable device for determining real-time evaluation of biodiesel blends. The device provides the user with blended FAME concentration in order for the user to compare with established specifications. Furthermore, the device enables the user to detect contaminants and unwanted materials within the biodiesel sample. The impedance spectroscopy data processing provides the user a broader functionality view of the biodiesel sample, and not simply the chemical make-up. Performance of the fuel can be affected by unwanted materials and by detecting the presence of the unwanted materials, the user is better able to make decisions that affect performance of the vehicle.

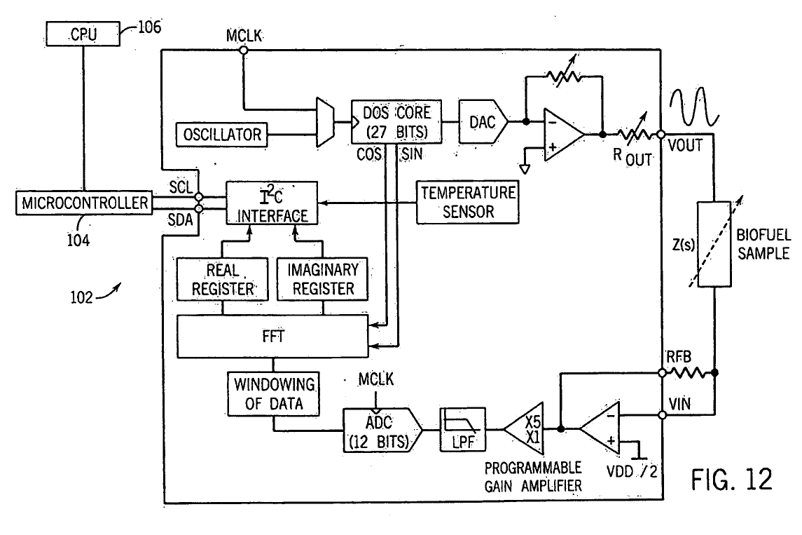

Another embodiment of the impedance spectroscopy system is shown in FIG. 12, which illustrates in block diagram form a portable, bench-top device 102. The biofuel sample can be tested external to the device 102, or alternatively internal to the device 102. A microcontroller 104 relays data to the central processing unit (CPU) 106 for calculation. Once the data has been calculated the biofuel concentration is sent to a graphical user interface (GUI) (not shown) by an I/O device (not shown). The device 102 has either an internal or external power source, as well as a suitable sampling fixture. The impedance data is acquired by the device 102 and transferred to the CPU for detection and identification, of elements within the sample as well as the relative concentrations of the elements. By example, the elements can include FAME, glycerol, residual alcohol, moisture, additives, corrosive compounds, unreacted feedstock (triglycerides), monoglycerides, diglycerides, and free (unreacted) fatty acids.

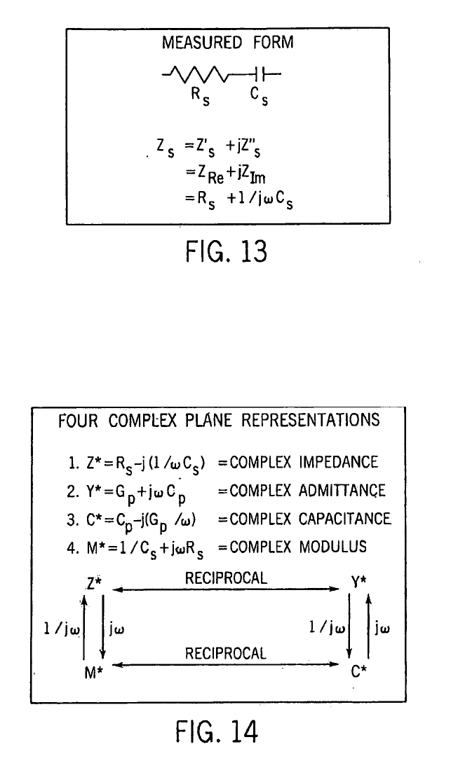

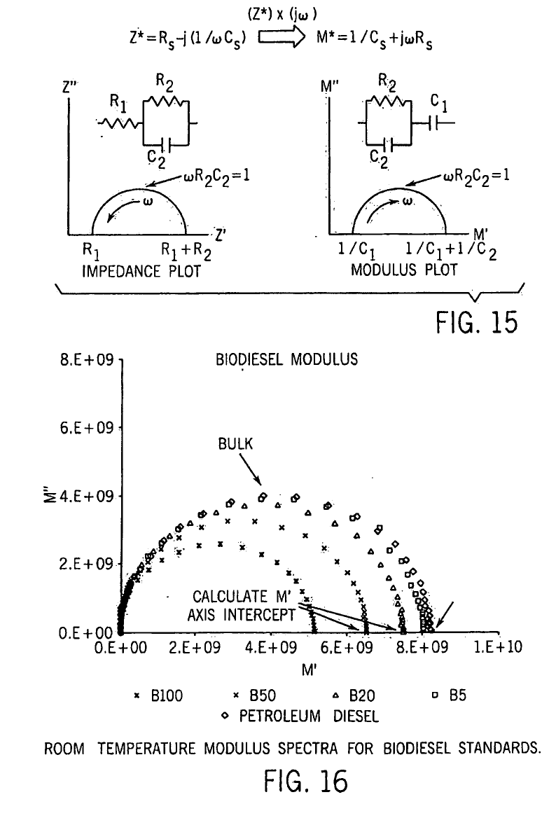

The biodiesel blend sample is tested and data is acquired by treating the sample as a series R-C combination. (See FIG. 13). The acquired sample data is converted by inversion of the weighting of the bulk media contribution to the total measured data response, wherein the value C₂ is typically a small value (See FIG. 14). This conversion minimizes the interfacial contribution of the bulk media, wherein the value C₁ is typically a large value (See FIG. 15). The real modulus transformation (M′) calculated for each biofuel sample is divided by the value (2*PI) in order to disguise the identity.

The biodiesel modulus spectra for the dedicated testing standards are provided in FIG. 16. The modulus data element M″ is plotted against the modulus data element M′. Data points for a petroleum diesel sample, as well as B5, B20, B50, and B100 were plotted. The complex impedance values (Z*) is converted to a complex modulus representation (M*) in order to inversely weight and isolate the bulk capacitance value from any interfacial polarization present within the sample. The M′ high frequency intercept via a semicircular fitting routine is then calculated.

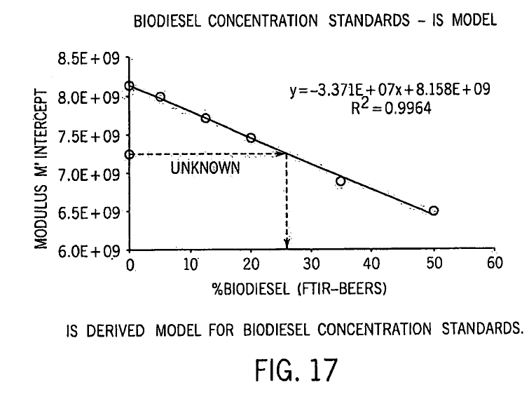

The biodiesel concentration standard, for which the impedance spectroscopy process will be measured against, is shown in FIG. 17. The previously calculated modulus (M′) intercept was plotted against the biodiesel concentration, as determined by the FTIR method. Equation Set 3 represents the derived algorithm.

Equation Set 3:

y=−3.371E+07x+8.158E+09

where x=% biodiesel, and R²=0.9964

Biofuel samples are tested using the analyzer 12. The impedance data measurement is focused upon the biofuel sample while the electrode influence and probe fixturing are minimized.

In an alternative embodiment, fuel analyzer system 10 and methods of the present invention are used to determine the FAME concentration in heating fuel. TIhe heating fuel sample is tested in a similar manner as that described for the biodiesel fuel blend. Alternatively, the system 10 can be used to analyze cutting fluids, engine coolants, heating oil (either petroleum diesel or biofuel) and hydrolysis of phosphate ester, which is used a hydraulic fluid (power transfer media).

In an alternative embodiment, the system 10 analyzes a biodiesel blend sample for the presence of substances selected from a group including second phase materials, fuel additives, glycerol, residual alcohol, moisture, unreacted feedstock (triglycerides), monoglycerides, diglycerides, and free (unreacted) fatty acids. In yet another alternative embodiment, the system 10 analyzes a biodiesel blend sample for the concentration of substances selected from a group including second phase materials, fuel additives, methanol, glycerol, residual alcohol, moisture, unreacted feedstock (triglycerides), monoglycerides, diglycerides, and free (unreacted) fatty acids.

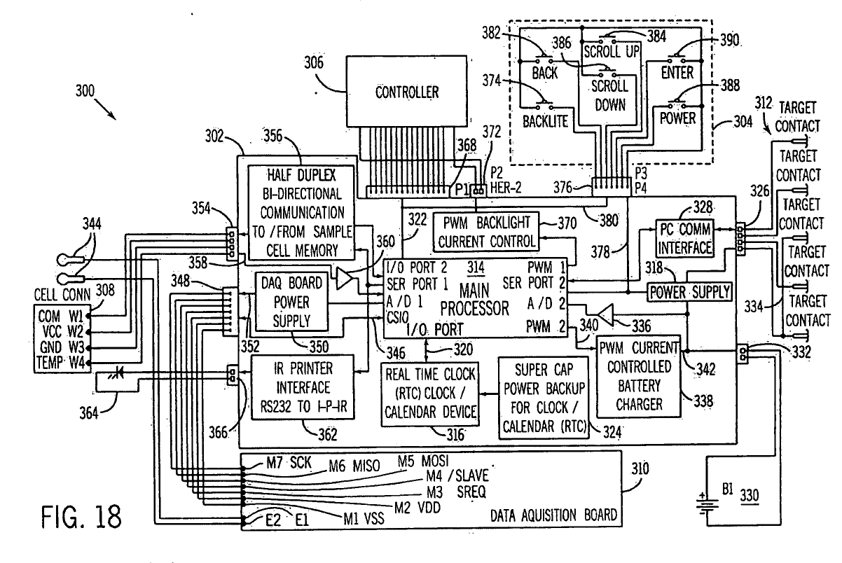

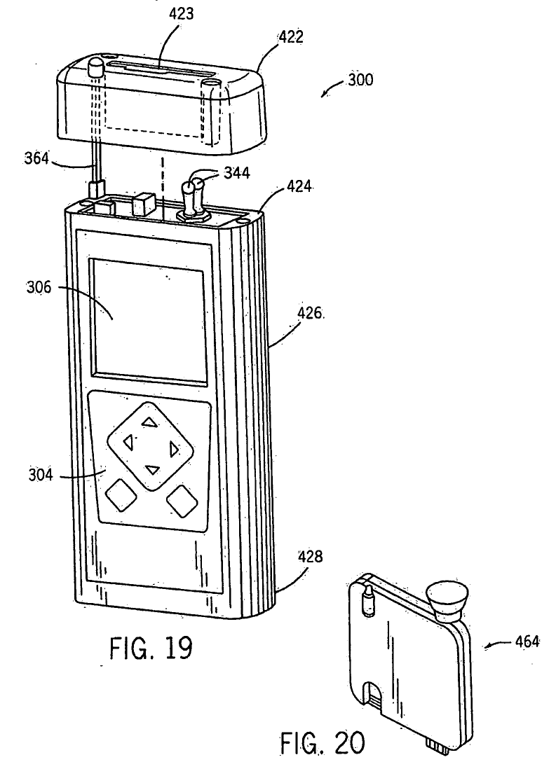

Another embodiment of an impedance spectroscopy system is illustrated in FIG. 19, which illustrates a perspective view of an exemplary hand-held impedance spectroscopy analysis device 300, which is operable with a sample cell, such as sample cell 464 illustrated in FIG. 19A, to measure and analyze a fluid sample in accordance with impedance spectroscopy methods similar to those discussed above to determine one or more fluid properties. The sample cell 464 serves as a reservoir for the fluid sample, and is preferably a one-time use detachable device that can be plugged into and removed from a slot 423 of the hand-held analysis device 300. The fluid sample is preferably a fuel sample such as a blended biofuel sample. The fluid properties which can be determined preferably include one or more of a biofuel (biodiesel) blend content or percentage, a total glycerin content or percentage, an acid number, and a methanol content or percentage. A block diagram of the hand-held analysis device 300 is illustrated in FIG. 18.

Referring to FIG. 18, the analysis device 300 includes a processing system 302 in operable association with a keypad 304, a display 306, a data acquisition board (DAQ board) 310, a light emitting diode (LED) 364, a battery 330, and a plurality of target contacts 312. The processing system 302 is also in communication with a cell connection unit 308 for connecting to the sample cell 464, which contains the fluid sample to be tested and analyzed. With respect to the processing system 302 in particular, it is capable of processing a wide variety of information received from one or more of the aforementioned components (e.g., keypad 304, the sample cell via connection unit 308, etc.) to determine fuel sample properties and display the same via the display 306. Each of the keypad 304, the display 306, the cell connection unit 308, the DAQ board 310, and the plurality of target contacts 312 are connected to the processing system 302 by way of one or more plugs (also referred herein as contacts, pins or connection points), as will be described in more detail below.

Further, as shown in FIG. 18, the processing system 302 includes a main processor 314 for processing various types of information; a real time clock (RTC)-calendar and clock device 316 for keeping track of current date and time; a power supply 318 for providing several fixed and regulated voltages to the various components of the hand-held analysis device 300; and a plurality of communication interfaces for connecting the components (through respective plugs) to the main processor, as well as other components. With respect to the RTC calendar and clock device 316, it is connected to the main processor 314 at a first Input/Output (I/O) port (e.g., I/O port 1) via duplex communication links 320 for providing continuous display of the current date and time on the display 306. Additionally, to accurately keep track of current date and time even when the hand-held analysis device 300 is powered off, the RTC calendar and clock device 316 is connected to a super cap power backup 324, which provides power to the RTC calendar and clock device when the hand-held device is turned off.

Power to the other components (e.g., keypad 304 and display 306) of the hand-held analysis device 300 is provided by the power supply 318. In particular, the power supply 318 receives an unregulated input voltage (e.g., ranging from the lowest battery voltage, about 5.5V to nominally 12V when seated in a charger base) and provides regulated lower voltages (e.g., 5V and 3.3V) for proper operation of the various components of device 300. Typically, the unregulated input voltage to the power supply 318 can be provided either via the target contacts 312 connected thereto through plugs 326 or through a battery 330 connected to the power supply through a plug 332. For example, a 12 Volt input from the target contacts 312 can be transformed into a 5 Volt power supply for powering the electronic circuitry of the main processor 314. Relatedly, a 3.3 Volt power supply can be generated for operation of the display 306. Similarly, regulated voltages for the keypad 304, and other components of the hand-held analysis device 300 are generated from the power supply 318.

With respect to the target contacts 312, in addition to being connected to the power supply 318, the target contacts are also connected to the main processor 314 for duplex communication therewith. Particularly, the target contacts 312 are connected to the main processor 314 at a serial port (e.g., Ser Port 2) via a PC communication interface 328 connected to the plugs 326. By virtue of providing the target contacts 312 connected to the main processor 314 and the power supply 318, the hand-held analysis device 300 can be plugged into a charging base (not shown) and/or docking station (not shown) connected to a wall plug power supply (also not shown) for providing an input power to the power supply 318. When seated in the charging base (or docking station), the hand-held analysis device 300 can be used for viewing (e.g., on display 306) and/or transferring stored results and/or data from the main processor 314 to another device. Notwithstanding the fact that five target contacts are shown in the present embodiment, this number can vary in other embodiments as well.

The target contacts 312 are equipped with a safety/sensing mechanism for avoiding electrical shock to a user on contact with the target contacts. In at least some embodiments of the present invention, the target contacts are designed such that at least two of the target contacts are connected together to form a relay control circuit. For example, as shown in the present embodiment, target contact 3 (TGT3) is connected to the target contact 5 (TGT 5) by communication link 334 to form the relay control circuit. In normal operating conditions when the hand-held analysis device 300 is removed from the charging base, the relay circuit is broken and, therefore, the deactivated relay in the charger base blocks current flowing through the target contacts 312, preventing electric shock to the user. Upon seating the hand-held analysis device 300 into the charging base, the relay control circuit is closed by connection with the electrical contacts of the charging base and current flows through the target contacts for providing power to the power supply 318. Further, although in the present embodiment two target contacts are connected together to form the relay circuit, in other embodiments, more than two contacts can be connected together as well.

In addition to employing the target contacts 312 for providing input power to the power supply 318, the hand-held analysis device 300 is also provided with the battery 330, which is preferably a rechargeable, replaceable battery connected to the power supply 318 of the processing system 302. The battery 330 is additionally connected to an analog-to-digital converter (e.g., A/D 2) port within the main processor 314 through an operational amplifier 336. By virtue of being connected to the power supply 318, the battery provides a source of input power for operating the hand-held analysis device 300 when the device is not seated in the charging base. This allows measurements from the fluid sample to be obtained, and processing performed, when the hand-held device 300 is operating in the battery mode.

As indicated above, the battery 330 is preferably a rechargeable battery that can be recharged upon seating the hand-held device 300 in the charging base. In particular, when the hand-held device 300 is seated in the charging base, and power is supplied from the power supply 318 to the main processor 314 (e.g., through the target contacts 312), the battery 330 is recharged by pulse width modulated (PWM) current controlled battery charger 338, connected on one end to a PWM port (e.g., PWM 2) of the main processor (e.g., by exemplary communication link 340), and on the other end to the battery (e.g., by communication link 342). In at least some embodiments of the present invention, the battery 330 is a 7.2 V Lithium-Ion (Li-Ion) battery, although other voltages and types of batteries are also contemplated.

Referring still to FIG. 18, the data acquisition board (DAQ Board) 310 is utilized for exciting electrodes 344 and acquiring measurement data indicative of the fluid sample. The acquired measurement data, for example magnitude and phase data at a predetermined set or plurality of frequencies, is then sent to the processing system 302 for analysis. Specifically, to obtain data from the fluid sample, the DAQ board 310, at contacts points E1 and E2, is connected to two electrodes 344 of the hand-held device 300. As explained more fully below, when the sample cell 464 is inserted in the hand-held device 300, the electrodes 344 are in contact with two metal plates of the sample cell, and the metal plates are in contact with the fluid sample in a reservoir formed between the metal plates in the sample cell. In at least some embodiments, the metal plates are arranged in a parallel plate electrode configuration, with a gasket between the metal plates. Thus, measurements corresponding to the fluid sample in the sample cell can be obtained by excitation of the electrodes 344 which contact the metal plates which contact the fluid sample in the sample cell.

In one embodiment, the DAQ board 310 is capable of providing a fixed amplitude excitation voltage (also referred herein as constant amplitude excitation voltage) to the electrodes 344, and measuring the current and phase angle of the fluid sample response relative to the excitation voltage. The process of applying an excitation voltage and measuring the resulting current and phase angle of the sample is repeated by varying the frequency of the voltage. For example, in at least some embodiments of the present invention, current and phase angle of the fluid sample relative to an excitation voltage can be measured for the predetermined plurality of frequencies, preferably approximately seven to ten different frequencies. In other embodiments, the number of and specific frequencies. chosen can be varied. Further, in other embodiments for obtaining measurements, rather than applying a fixed excitation voltage, a fixed excitation current at varying frequencies can be applied and the resulting voltage and phase angle can be measured in at least some other embodiments for obtaining measurements. Also, the excitation voltage and/or excitation current need not be fixed. Rather, a varying current and/or voltage can be applied for exciting the fluid sample for data.

Subsequent to obtaining measurement data from the fluid sample, the DAQ board 310 communicates the sample measurement data to the main processor 314 for storage and processing. Particularly, the DAQ board 310 is connected to the main processor 314 at a CSIO port through a plug 348 and a duplex clocked (synchronous) serial I/O 346. Power to the DAQ board 310 is provided by a DAQ board power supply 350, controlled by the main processor 314. The DAQ board power supply 350 is additionally connected to the DAQ board 310 through the plug 348, as shown by a one-way communication link 352. By virtue of having a separately controlled DAQ board power supply 350 for the DAQ board 310, power to the DAQ board can be turned off when the hand-held device 300 is not actively making a measurement, thereby providing a significant saving of battery power.

The main processor 314 is also in bi-directional communication with the sample cell when it is plugged into the hand-held device 300. In particular, a sample cell circuit (not shown) of the sample cell is connected, via cell connection unit 308, plug 354, and circuit 356, to main processor 314. The sample cell circuit includes a memory to store information such as an identifier and one or more calibration parameters relating to that sample cell. The sample cell memory is a non-volatile memory capable of storing information even when the power to the sample cell is turned off. The memory is also preferably a memory which can be both read and written to. In at least some embodiments of the present invention, the memory can be configured as a removable memory device (e.g., a memory stick) that can be plugged and/or unplugged (e.g., via a Universal Serial Bus (USB) port) into the sample cell as desired.

In at least one embodiment, the sample cell memory can initially store a specific identifier, such as a serial number, which is unique to that sample cell. The main processor 314 is programmed to read the serial number and proceed with obtaining measurements only if that sample cell has not been previously used. In other words, the sample cell is a one-time use device, and re-use of the sample cell can be prevented.

Typically, the stored calibration parameters are also specific to the sample cell and relate to electrical characteristics of the dry (i.e. unfilled) sample cell, such as can be determined from impedance measurements of the dry sample cell at one or more frequencies. Thus, in addition to utilizing the measurement data corresponding to the fluid sample obtained by the DAQ board 310, the main processor 314 also reads the one or more calibration parameters from the sample cell memory and employs these parameters in the analysis of the fluid sample. Specifically, during operation, the one or more calibration parameters of the sample cell are provided to the main processor 314 via the cell connection unit 308, which is connected to the main processor via the plug 354 and half-duplex bi-directional communication interface 356. The half-duplex bi-directional communication interface 356 is additionally connected to the main processor 314 at a serial port (e.g., Ser Port 1) of the main processor.

In addition to calibration information, the main processor 314 preferably utilizes temperature information of the fluid sample in the determination of fluid sample properties, and produces results based upon the current temperature of the sample. Therefore, by virtue of determining the sample temperature and accounting for the temperature variations during processing, more accurate results can be obtained. In particular, temperature of the sample is obtained by a temperature sensor (not shown) provided on or within the sample cell. The temperature sensor determines the approximate current temperature of the fluid sample and transfers the temperature information through the cell connection unit 308 to the main processor 314. As shown, a separate voltage based temperature line 358 is connected to the A/D 1 port of the main processor 314 via an operational amplifier 360. Although, in the present embodiment, the A/D 1 port is connected to both the DAQ board power supply 350 and the voltage based temperature line 358, in alternate embodiments, separate analog-to-digital ports can be utilized.

Upon collection of the calibration and temperature information from the sample cell and magnitude and phase angle data from the sample fuel, the main processor 314 processes the information according to a stored algorithm, such as the algorithm explained above. In some embodiments, the processing system 302 and DAQ board 310 are programmed to determine one or more fluid sample properties using an improved algorithm which takes into account other variables, including for example the temperature of the sample and the calibration parameters mentioned above. Generally, such an improved algorithm can be developed using a data gathering technique in which a large set of data is gathered from various samples and then using a data mining technique to statistically analyze the data set, as more fully explained below.

Typically, the IR printer interface 362 employs a driver for converting RS232 ASCII code to the IR printer code, although other types of drivers can potentially be used. In at least some embodiments of the present invention, an HP 82240B IR printer available from the Hewlett-Packard Company of Palo Alto, Calif. is used. In alternate embodiments, printers other than the one mentioned above, can be used as well. Further, upon availability of results that can possibly be printed, the LED 364 is activated to signal to the printer the availability of the results, and communicates the text to be printed to report the results. The photodiode is connected to the IR printer interface 362 via a plug 366. In addition to printing data on a printer, the present invention also provides the display 306, where results can alternatively be viewed.

With respect to the display 306, it is preferably a 128×128 pixel graphical LCD backlight display organized in eight lines of text, with each line capable of displaying 16 characters. In at least some embodiments, an Ampire Controller HD66750 display available from the Hitachi, Ltd of Marunouchi Itchome, Chiyoda, Tokyo, Japan can be used. The display 306 is connected to the main processor 314 by way a plug 368 connected to the I/O port 2 of the main processor. The intensity (e.g., brightness) of the display 306 can be manipulated by way of a pulse width modulated (PWM) backlight current control 370 connected to a pulse width modulated port (e.g., PWM 1) of the main processor 314. The (PWM) backlight current control 370 is connected to a plug 372 that further connects to a plurality of Light-Emitting-Diodes (LED) on the display 306. By virtue of altering the current by the PWM backlight current control 370, the intensity of the backlight of the display 306 can be altered.

Further, the display 306 can be maneuvered by way of the a menu system having a set of keys (e.g., the keypad 304), which is provided with a plurality of buttons that can be depressed to power on/off the hand-held device 300 from the battery mode and/or maneuver the display 306. To achieve such functionality, the keypad 304 is connected to the main processor 314 and the display 306. For example, by virtue of a plug 376, the keypad 304 is connected to the main processor 314 via a communication link 378, and to the display 306 via a communication link 380. The keypad 304 is provided with a plurality of buttons, including, for example, a “BACK LITE button 374 for turning on/off the backlight of the display 306, a “BACK” button 382 to return to a previous display, and “SCROLL UP” and “SCROLL DOWN” buttons 384 and 386, respectively, for moving the display up and down. Also provided is a “POWER” button 388 to, turn on/off the hand-held device 300 from the battery mode and an “ENTER” button 390 to move a cursor on the display 306 and/or display a new value. By virtue of providing the aforementioned keys on the keypad 304, those keys can be employed for moving a cursor (or a highlight) on the display 306, and also for performing actions that are generally intuitively understood by the highlighted item. Notwithstanding the fact that six buttons have been described above with respect to the keypad 304, additional buttons providing additional functionality such as a “RIGHT” key and a “LEFT” key are contemplated in alternate embodiments.

Referring again to FIG. 19, the hand-held analyzer device 300 includes a shroud assembly 422, a top cover assembly 424, a case assembly 426 and a bottom cover assembly 428. The shroud assembly 422 includes a slot 423 for receiving the sample cell 464. The case assembly 426 houses and protects many of the components shown in FIG. 18, including components such as the processing system 302 and the DAQ board 310 which are situated within the case assembly and components such as the display 306 and keypad 304 which are situated to be accessible to a user. The top cover assembly 424 acts as the interface between the sample cell 464 and the processing system 302 and DAQ board 310, and includes the electrodes 344 which contact metal plates of the sample cell when the sample cell is inserted in the slot 423.

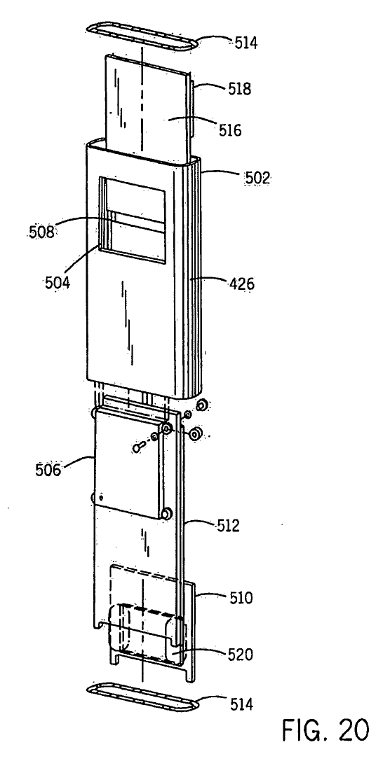

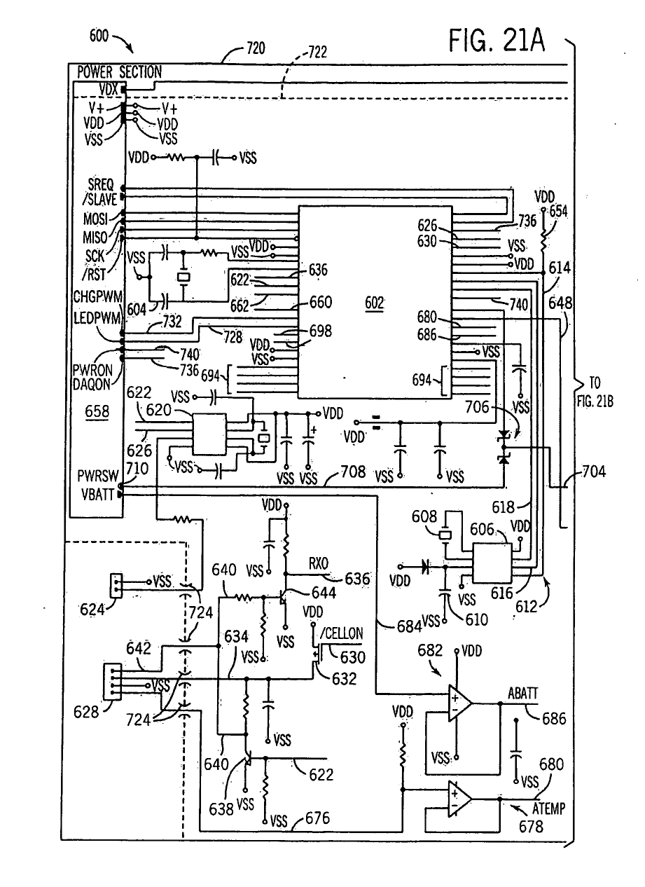

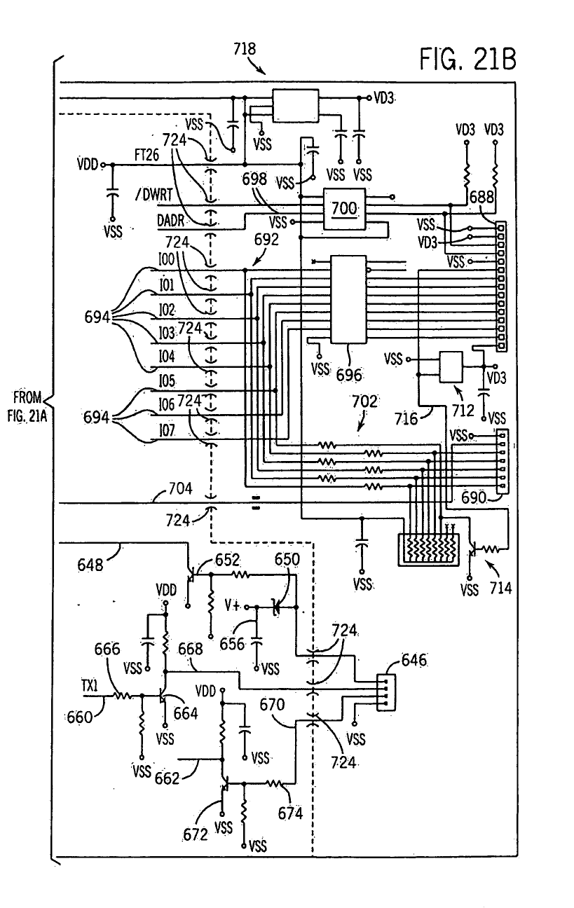

Referring now to FIG. 20, another partially exploded front perspective view of the case assembly 426 is shown, in accordance with at least some embodiments of the present invention. As shown, the case assembly 426 includes a case 502 having a touch pad 504 and encompassing a main printed circuit board (PCB) 506 and a DAQ PCB 516, on which are formed the various electronic circuits described above and additionally described below, and DAQ and battery retainers 508 and 510, respectively, and a DAQ shield 518. An insulator shield 512 and a pair of end cover gaskets 514 are additionally shown. A battery 520 (i.e., battery 330 of FIG. 18) is additionally provided.

Turning now to FIG. 21, a main board circuit 600 illustrating additional details of processing system 302 of FIG. 18 is shown, in accordance with at least some embodiments of the present invention. As shown, the circuit 600 includes a main processor 602 (e.g., the main processor 314 of FIG. 18) that processes the data collected from the sample fluid being tested and additionally performs various calculations to determine, for example, the FAME percentage, of that sample fluid, along with one or more additional fluid properties. In addition, the main processor 602 governs the operation of various other components, described below, that are present in the hand-held device 300 (See FIG. 18). In at least some embodiments, the main processor 602 can be an ATMEGA644P 8-bit RISC processor available from the ATMEL corporation of San Jose, Calif. In other embodiments, other microprocessors capable of performing the functions of the main processor 602 can be employed as well.

Furthermore, all of the operations of the main processor 602 are performed in synchronization with a clock signal generated by way of a crystal oscillator 604. In at least some embodiments, the crystal oscillator 604 has a frequency of 18.432 MHz, although other frequency crystal oscillators can be employed as well. In addition to the main processor 602, the circuit 600 also includes a real time clock (RTC) and calendar chip (referred herein as a chip) 606 (e.g., the RTC clock and calendar device 316 of FIG. 18) for keeping track of current time and date. The chip 606 is a low power consumption chip that employs a crystal oscillator 608 having, in at least some embodiments, a frequency of 32.768 KHz for tracking time. In alternate embodiments, other frequency crystal oscillators are contemplated and considered within the scope of the present invention. Further, the chip 606 is capable of operating on an alternate source of power supply (e.g., the super cap power backup 324 of FIG. 18) that powers the chip when the primary source of power (e.g., power from a wall socket) is switched off or unavailable. In at least some embodiments, the alternate power source for the chip 606 can come from a capacitor (e.g., super capacitor) 610, although other sources of alternate power (e.g., lithium batteries) can be employed in alternate embodiments.

Additionally, the operation of the chip 606 is controlled by the main processor 602, which communicates with the chip via a plurality of serial interfaces 612. In particular, and as shown, the plurality of serial interfaces 612 can include a serial data clock input line (RTCCK) 614 for synchronizing communication between the main processor 602 and the chip 606, a bi-directional data line (RTCDT) 616 for providing serial data input/output and an interrupt line (RTCINT) 618 for programming the chip for operation. For example, in at least some embodiments, the interrupt line 618 can be employed for setting up a one second heartbeat of the clock within the chip 606. In other embodiments, the interrupt line 618 can be employed for setting up the clock including, for example, changing and initializing the date and time of the chip 606.

The circuit 600 further includes a secondary processor 620 that converts an RS-232 format output from the main processor 602 into a format required, for example, by an Hewlett Packard (HP) infrared printer for printing. In at least some embodiments, the secondary processor 620 can be a PIC12F508-I/MS 8-bit flash microcontroller available from the Microchip Technology, Inc. of Chandler, Ariz. In other embodiments, other micro-controllers for facilitating RS-232 format into the HP-IR format can be employed as well.

The secondary processor 620 can communicate with the main processor 602 via a serial port, described below. More specifically, information from the main processor 602 can be sent on a TXO line 622 (pin 10 of the main processor) to input pin 5 of the secondary processor 620, such that data (in RS-232 format) sent by the main processor is converted into a series of fast pulses of infra-red light that are transmitted to an HP IR printer (not shown) for printing. An LED 624 (e.g., the LED 364 of FIG. 18) connected to the secondary processor 620 indicates availability of the printing results on the HP IR printer.

The secondary processor 620 additionally employs an/IRON line 626 to establish communication with the main processor 602 for printing. Particularly, the/IRON line 626 is connected between pin 41 of the main processor 602 and pin 6 of the secondary processor 620 for controlling the printing operation. By activating the/IRON line 626, the information sent on the TXO line 622 is received by the secondary processor 620 and processed for printing. However, when printing is not required, the/IRON line 626 can be de-activated, which causes the secondary processor 620 to ignore any data sent by the main processor on the TXO line 622. Thus, controlling the operation (reading or ignoring data on the TXO line 622) of the secondary processor 620 by virtue of employing the/IRON line 626 is particularly advantageous insofar as the TXO line can be employed for transmitting information to at least some additional components.

For example, when the secondary processor 620 is powered off (e.g., by de-activating the/IRON line 626), information on the TXO line 622 can be transmitted to the sample cell 464 (see FIG. 19A) via a sample cell connection unit (e.g., the cell connection unit 308 of FIG. 18) 628. Thus, one communication port (the TXO line 622) on the main processor 602 can be employed for driving both the IR printer (via the secondary processor 620) and the sample cell 464 (via the sample cell connection unit 628). Notwithstanding the fact that the TXO line 622 drives both the IR printer and the sample cell, it will be understood that such communication between those two devices does not occur simultaneously. Rather, the operation of each of those devices is controlled by respective control signals generated by the main processor 602. For example, and as indicated above, the operation of the HP IR printer can be controlled by way of the/IRON line 626. Relatedly, the operation (e.g., powering on/off of the sample cell can be governed by a CELLON line 630 generated on pin 40 of the main processor 602. In particular, the CELLON line 630 is communicated to the sample cell through a transistor 632 and the sample cell connection unit 628, as indicated by an interconnect link 634.

Upon powering on the sample cell by actuating the CELLON line 630, a bi-directional communication between the sample cell and the main processor 602 can be established by way of the TXO line 622, described above, and an RXO line 636, described below. Specifically, information from the main processor 602 can be transmitted for reading by the sample cell on the TXO line 622 through a transistor 638 and interconnect 640 to the sample cell connection unit 628 via interconnect 642. Relatedly, information from the sample cell can also be conveyed to the main processor 602 via the sample cell connection 628. Particularly, information can be transmitted to the main processor 602 via the interconnect 642 connected to the sample cell connection 628 leading to the RXO line 636 via the interconnect 640 and transistor 644 to the main processor 602. Thus, the sample cell connection 628 includes a bi-directional communication link (e.g., the half-duplex, bi-directional communication block 356 of FIG. 18) that is capable of both receiving information from and transmitting information to the main processor 602 via the respective TXO line 622 and the RXO line 636.

In at least some embodiments, the transistors 638 and 644 can be an MMBT3904 device available from the-Fairchild Semiconductor Corporation of South Portland, Me. Relatedly, in at least some embodiments, the transistor 632 can be an NTR4101P Metal Oxide Semiconductor Field Effect Transistor (MOSFET) available from the ON Semiconductor of Phoenix, Ariz. Notwithstanding the fact that specific devices for the transistors 632, 638 and 644 have been described above, it should be understood that the usage of such devices is merely exemplary. In other embodiments, other transistors capable of providing the functionality of the transistors 632, 638 and 644 can be employed as well.

Referring still to FIG. 21, the main board circuit 600 can be powered by plugging the hand-held analyzer device 300 (See FIG. 18) into a charger base or docking station (not shown). In particular, communication between the hand-held device 300 and the charger base can be established by way of a connector 646 (e.g., the pad 326 in FIG. 18) on the main board circuit 600, which communicates the presence of the charger base to the main processor 602. It can be noted that the connector 646 has only four connection points that represent four out of the five target contacts 312 on the charger base. While there are five target contacts, there are only four signals within the monitor because TGT3 is connected to TGT1. TGT3 returns the signal of TGT1 back to the charger base to act as a relay control signal.

Furthermore, information regarding whether the hand-held device 300 is seated within the charger base or not is provided by an ACOFF line 648 connected between the connector 646 and the main processor 602. Specifically, upon seating the hand-held device 300 into the charger base, a voltage signal provided by an external power source (e.g., a wall socket) is detected at a diode 650, which turns on a transistor 652 causing the ACOFF line 648 connected to the main processor 602 to be pulled low by a resistor 654. Relatedly, disengagement of the hand-held device 300 from the charger base causes the transistor 652 to be turned off (e.g., due to no voltage detection at the diode 650), which in turn causes the resistor 654 to pull the ACOFF line 648 high. Thus, in at least some embodiments, a low level on the ACOFF line 648 indicates engagement, while a high level indicates disengagement of the hand-held device 300 with the charger base. In other embodiments, the ACOFF line 648 can be set such that high and low states of the ACOFF line indicate respective engagement and disengagement of the hand-held device 300 with the charger base.

With respect to the diode 650 in particular, it serves multiple purposes. First, as indicated above, upon seating the hand-held device 300 into the charger base, a voltage (e.g., 12 volts) is detected at that diode. The diode 650 blocks energy from the battery coming “out” of the target contacts 312. Furthermore, the diode 650 provides protection of polarity by blocking any outbound current/voltage. Additionally, the 12 volt voltage appearing at the diode 650 is conveyed via a V+signal 656 to a power section 658 for conversion into 5 volts for operating various components within the hand-held device 300. The power section 658 is described in greater detail below. In at least some embodiments, the diode 650 can be a B340LA schottky barrier rectifier available from the Diode, Inc Company of Dallas, Tex. Other blocking diodes can be employed in other embodiments as well. Similarly, the transistor 652 can be the MMBT3904 device in some embodiments, although other similar transistors can be utilized in alternate embodiments.

Further, in addition to notifying the main processor 602 of the engagement/dis-engagement of the hand-held device 300 with the charger base, a bi-directional communication between the main processor and the charger base can be facilitated by employing a TX1 line 660 and an RX1 line 662. Similar to the TX0 and the RX0 lines 622 and 636, respectively, the TX1 line 660 and the RX1 line 662 serve as Universal Asynchronous Receiver/Transmitter (UART) ports. With respect to the TX1 line 660 in particular, it is connected between the main processor 602 and the connector 646 for facilitating transmittal of information from the main processor to the charger base. More particularly, information from the main processor 602 can be sent by transmitting information on the TX1 line 660, which drives a transistor 664 through resistor 666 to drive the connector 646 on interconnect 668. Relatedly, information from the charger base to the main processor 602 can be communicated on interconnect 670, which turns on a transistor 672 via resistor 674 to drive the RXI line 662, of the main processor 602. The transistors 664 and 672 are merely inverter interface transistors (e.g., the MMBT3904 devices) that protect the components on the hand-held device 300 from transient currents (or voltages) while providing voltage level shifting.

Referring still to FIG. 21, the temperature measurements performed by the sample cell are provided by the sample cell connection unit 628 via interconnect 676 to an operational amplifier (op-amp) 678. The operational amplifier 678 buffers the incoming signal to provide an analog ATEMP output signal sent along an ATEMP line 680 that is connected to the main processor 602. Within the main processor 602, the ATEMP line 680 is connected to an analog-to-digital converter for conversion into a digital value for performing various calculations based on the measured temperature. In at least some embodiments, the operational amplifier 678 can be an AD8606AR device from the Analog Devices, Inc. Company of Norwood, Mass. In other embodiments, other operational amplifiers can be employed as well.

Additionally, as shown, the circuit 600 includes an additional op-amp 682 (e.g., the buffer 336 in FIG. 18), which receives a VBAT signal from the power section 658 along VBAT line 684 representative of a battery voltage. Upon receiving the VBAT line 684, the op-amp 682 buffers the VBAT signal to output an ABATT signal along ABATT line 686 that is provided to the main processor 602. Similar to the analog-to-digital temperature conversion of the ATEMP signal within the main processor 602, the ABATT signal along ABATT line 686 is connected to an analog-to-digital converter within the main processor to convert the ABATT signal into a digital voltage signal. By virtue of reading the battery voltage, the main processor 602 can alert a user of the battery status (e.g., amount of change, time left). The op-amp 682 in some embodiments can be AD8606AR device, described above, although other devices can be used as well in other embodiments.

In addition to the aforementioned components, the main board circuit 600 includes monitor and keyboard communication connection units 688 and 690, respectively, which are employed for establishing communication between the monitor 306 (see FIG. 18) and keyboard 304 (see FIG. 18), respectively, and the main processor 602. As shown, the monitor 306 and the keyboard 304 are each connected to the main processor 602 (through the monitor and the keyboard communication connection units 688 and 690, respectively) via a plurality of commonly shared communication links 692. The communication links 692 are employed for both reading information from the keyboard 304 and writing information to the monitor 306. As further shown, the communication links 692 include eight input/output data lines (IO0-IO7) 694, each of which is connected to the main processor 602 for facilitating parallel communication between the main processor 602 and the monitor 306 and the keyboard 304. In particular, information from the main processor 602 is output to the monitor 306 via the data lines 694 going through a voltage converter 696 to the monitor via the monitor communication connection unit 688.

With respect to the voltage converter 696 in particular, it facilitates communication between devices operating on varying voltages. For example, the voltage converter 696 accepts the data lines 694 from the main processor 602 that operates on a 5 volt voltage level and converts that voltage level into a 3 volt voltage level on which the monitor operates. In at least some embodiments, the voltage converter 696 can be an SN74CB3T3245 high-speed FET bus switch manufactured by the Texas Instruments, Inc. Company of Dallas, Tex. In other embodiments, other voltage converters that are commonly available can be utilized as well.

Thus, data from the main processor 602 is transmitted in parallel to the monitor 306 on data lines 694 passing through the voltage converter 696 for facilitating communication between the main processor and the monitor. Furthermore, the communication between the main processor 602 and the monitor 306 is controlled by way of a pair of control lines 698 (e.g., a data write line/DWRT and a data address line DADR) passing through an electronic device 700. The electronic device 700 in at least some embodiments is a dual-bit dual-supply bus transceiver designed for asynchronous communication between data buses manufactured by the Texas Instruments Company. In other embodiments, other electronic devices capable of providing similar functionality as that of the electronic device 700 can be employed as well.

In addition to communicating with the monitor 306 via the data lines 694, the main processor 602 additionally accepts input from the keyboard 304 via the data lines. Specifically, the data lines 694 are periodically (e.g., every 2 milliseconds) turned into input data lines that read information from the keyboard 304 via a series of resistors 702. The resistors 702 are specially designed resistors having a low enough value to accurately communicate information from the keyboard 304 to the main processor 602, while at the same time having a value high enough to prevent interference when the data lines 694 are being employed as output data lines transmitting information to the monitor 306. The keyboard 304 additionally includes a “power” key (key 388 in FIG. 18) of the keyboard connection unit 690 on interconnect 704 that is employed for powering on/off the main processor 602. In particular, the interconnect 704 extends to a pair of blocking diodes 706, such that upon pressing the “power” key 388 on the keyboard 304, the pair of diodes cause an input on the main processor 602 to go low, thereby turning off the power supply to that processor. Relatedly, to power on the main processor 602, pressing the “power” key again causes the pair of diodes 706 to turn the input on the main processor high by drawing power through interconnect 708 connected to a power switch (PWRSW) 710 of the power section 658. In at least some embodiments, each of the pair of the blocking diodes 706 can be a BAT54C device available from the Fairchild Semiconductor Corp. In other embodiments, other blocking diodes can be employed as well.

Also provided on the main board circuit 600 is a reset chip 712 that is employed for resetting the monitor 306 (e.g., upon start-up). In particular, a reset signal is used to drive a transistor 714 via an interconnect link 716. The transistor 714 in general acts like a push button, which when pressed, subsequent to powering on the hand-held device 300, can be employed to reset the monitor 306. The monitor 306 is generally reset before initiating communication with the main processor 602. In at least some embodiments, the reset chip 712 can be an MCP809 reset chip available from the National Semiconductor Corporation of Santa Clara, Calif. A voltage converter 718 additionally facilitates voltage conversion from 5 volts down to 3.3 volts to provide a VDX signal on line 720 that is sent to the power section 658 for controlling the intensity of the backlight of the monitor 306 in a manner described below. The voltage converter 718 in at least some embodiments can be an LP2985 device available from the Texas Instruments, Inc. Company. In other embodiments, other voltage converters for converting 5 volts into 3.3 volts can be employed as well.

Furthermore, to protect the components (e.g. from RF) on the circuit 600, various components on the circuit are shielded within a shielding box 722 (represented by dashed lines) such that communication between the components within the shielding box and the components outside the shielding box is facilitated via a plurality of feed through caps 724.

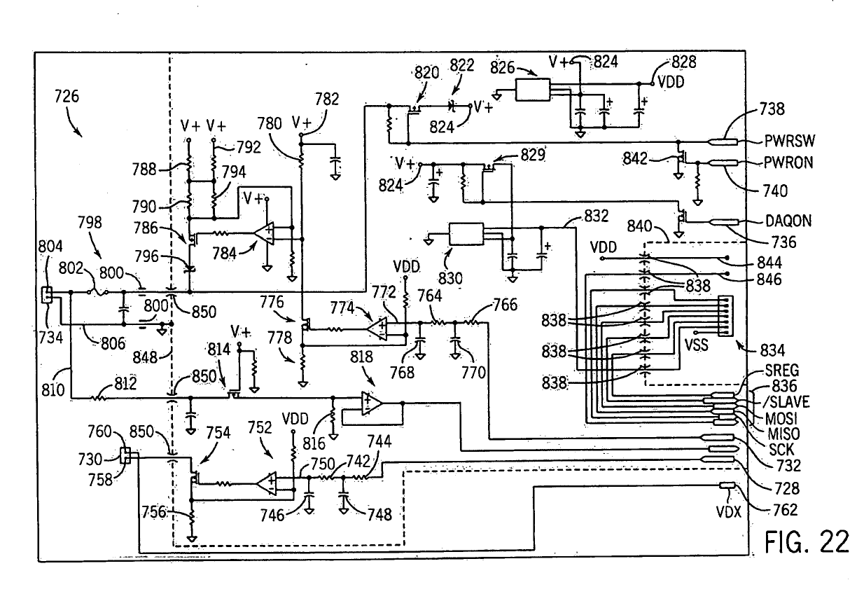

Referring now to FIG. 22, an exemplary circuit 726 of the power section 658 is shown in accordance with at least some embodiments of the present invention. As shown, the circuit 726 receives a plurality of control signals from the main processor 602 to perform a wide variety of power related operations. For example, the circuit 726 receives a Light Emitting Diode Pulse Width Modulation (LEDPWM) signal 728 for varying the intensity of an LED backlight 730 of the monitor 306, a charge pulse width modulation (CHGPWM) signal 732 for controlling the amount of current being delivered to charge a battery 734, a (SMPLON) signal 736 for powering the DAQ board 310 (See FIG. 18), a power switch (PWRSW) signal 738 for powering the hand-held device 300 and a power on (PWRON) signal 740 for maintaining the power to the hand-held device 300 after the device has been powered up (via the PWRSW signal). With respect to the LEDPWM signal 728, that signal is a fixed frequency variable width signal, the width being varied under the control of software programmed into the main processor 602. Thus, the LEDPWM signal 728 is a control signal provided by the main processor 602 to the power section 658 for controlling the brightness of the LED backlight 730. Within the power section 658, the LEDPWM signal 732 is filtered and converted into a DC level (relative to the width) via a pair of resistors 742 and 744 and their respective capacitors 746 and 748, and input via input 750 into a current generator 752. In at least some embodiments, the current generator 752 can be an LMC6484 operational amplifier available from the National Semiconductor Corp. Company. In other embodiments, other current generators can be employed as well.

The DC level signal filtered by the resistors 742 and 744 (and capacitors 746 and 748) defines the current to be drawn through the LED backlight 730 of the monitor 306 to control the intensity thereof. The intensity of the LED backlight 730 can particularly be controlled by way of the current generator 752 operating in conjunction with a transistor 754 to form a servo circuit. As a result, the current generator 752 drives the transistor 754 until voltage across a resistor 756 equals the voltage at the input 750 of the current generator. Thus, by virtue of controlling the voltage at the input 750 of the current generator 752, the main processor 602 can control the voltage at the resistor 756 by driving the transistor 754. In at least some embodiments, the transistor 754 can be a BSS138 FET device available from the Fairchild Semiconductor Corp., although other transistors capable of operating in conjunction with the current generator 752 can be utilized as well.

In particular, the voltage at the resistor 756 can be controlled by way of varying the voltage drawn from a cathode 758 of the LED backlight 730 due to the transistor 754 being turned on. Voltage to the cathode 758 of the LED backlight 730 in turn is provided through an anode 760, which is connected to a VDX signal 762 coming from the VDX line 720 on the main board circuit 600. Thus, a voltage (e.g., 5 volts) coming in via the VDX line 720 is provided to the power section 658, which in turns communicates that signal as the VDX signal 762 to the anode 760 of the LED backlight 730. The anode 760 transfers that voltage to the cathode 758 of LED backlight 730, which in turn transmits the voltage to the transistor 754 when that transistor is driven to control the voltage at the resistor 756 to be equal to the voltage at the input 750 of the current generator 752. By virtue of controlling the voltage at the resistor 756, the current at that resistor can be varied to control the current at the LED backlight to modify the intensity thereof. Furthermore, the value of the resistor 756 can vary depending upon the embodiment. In at least some embodiments, the resistor 756 can be a 68 ohm 0.5 watt resistor. In other embodiments, resistors large enough to prevent damage to the LED backlight can be utilized.

In addition to the LEDPWM signal 728 to control the intensity (e.g., brightness) of the LED backlight 730, the circuit 726 receives the CHGPWM signal 732 to control the current for charging the battery 734. Similar to the LEDPWM signal 728, the CHGPWM signal 732 is filtered through a pair of resistors 764 and 766 and associated capacitors 768 and 770, respectively, to convert the CHGPWM signal into a DC level signal that is provided as input 772 to current generator 774. Also similar to the current generator 752, the current generator 774 operates in conjunction with a transistor 776 to drive the transistor until voltage at the input 772 is equal to the voltage at a resistor 778. Thus, by virtue of altering the voltage at the input 772, the voltage at the resistor 778 can be altered. In addition, the voltage (and thus the current) at the resistor 778 is reflected at, and is equal to, the voltage (and therefore the current) at a resistor 780, which is referenced to a V+voltage 782 for creating a reference voltage. The voltage across the resistor 780 drives another current generator 784 and transistor 786 to provide a servo action of a reverse polarity.

By virtue of the servo action the current generator 784 drives the transistor 786 until the voltage at resistors 788, 790, 792 and 794 is equal to the voltage at the resistor 780. In at least some embodiments, each of the resistors 788-794 can be a 10 ohm 1 watt resistor wired together to provide a 4 watt resistor. By virtue of employing four smaller resistors connected together to form a bigger resistor, excessive heat generation can be prevented. Notwithstanding the fact that in the present embodiment, four resistors combined together to form a 4 watt resistor have been employed, in other embodiments this need not be the case. Rather, other resistor configurations including a single 4 watt resistor or possibly more than 4 resistors can be employed. Thus, the current to control the charging of the battery 734 can be set by varying the voltage at the input 772 of the current generator 774, which in turn varies the voltage at the resistors 778 and 780. The change in voltage at the resistor 780 is then reflected (e.g., by driving the transistor 786) at the resistors 788-794 and the current at those voltages can then be determined by applying ohm's law (V=1 R). The charging current at the resistors 788-794 can then be provided by way of a diode 796 via filtering circuit 798 having ferrite beads 800 and a resettable fuse 802 to a positive terminal 804 of the battery 734. Thus, the current through the diode 796 flows through the filtering circuit 798 to the battery 734 and back to ground via interconnect 806 to charge the battery.

In at least some embodiments, the diode 796 can be the B34OLA device from the Diodes, Inc. Company although other diodes can potentially be employed in other embodiments. Similarly, the resettable fuse 802 and the ferrite beads 800 can be MINISMDO75-2 and HZ0805E601R-00 devices available from Tyco Electronics Corp. Company of Berwyn, Pa. and the Laird Technologies Company of St. Louis, Mo., respectively. In other embodiments, other similar devices can be employed as well for both the resettable fuse 802 and the ferrite beads 800.

Referring still to FIG. 22, in order to assess the progress of charging the battery 734, and also to assess the decay of charge of the battery, interconnect 810 is connected via a high impedance resistor 812 to a transistor 814. Upon detecting a voltage at the resistor 812, the transistor 814 is turned on causing a voltage division between the resistor 812 and another resistor 816. The divided voltage is then buffered by an operational amplifier 818, the output of which is provided to the VBAT line 684 that is read into the main processor 602 to convey the status of the battery 734, in a manner described above with respect to FIG. 21.

Subsequent to charging the battery 734 in a manner described above, the charged battery can then be utilized to power (in a battery mode) the hand-held device 300. Generally speaking, the battery 734 can be employed for providing power (in a battery mode) to the hand-held device 300 until the battery has charge remaining therein, subsequent to which re-charging of the battery becomes essential. Typically, battery power for powering the hand-held device 300 can be provided through the positive terminal 804 of the battery 734, which is conveyed via the resettable fuse 802 and the filtering circuit 800 to drive a transistor 820. The transistor 820 serves as the main power switch when operating in the battery mode. Upon turning on the transistor 820 (e.g., due to voltage from the battery 734 in the battery mode), power (e.g., voltage) is provided through diode 822 to a reference point 824. The diode 822 is a uni-directional blocking diode that prevents voltage from (e.g., the external power source) the reference point 824 to go into the battery 734 via the transistor 820, thereby preventing any damage to the battery.

The voltage at the reference point 824 is then employed for powering a voltage regulator 826, which provides a volt power supply to power various components on the hand-held device 300. The 5 volt power supply is output from the voltage regulator along interconnect 828 as a VDD power supply. In at least some embodiments, the voltage regulator 826 can be an LM2937IMP-5.0 device from the National Semiconductor Corp. In other embodiments, other voltage regulators can be utilized as well.

In addition to powering the voltage regulator 826, the voltage at the reference point 824 is also provided to a transistor 829. The operation of the transistor 829.(e.g., turning on and off) is controlled by the SMPLON signal 736, which in turn is controlled by the main processor 602. As indicated above, the SMPLON signal 736 is employed for powering up the DAQ board 310. Advantageously, by virtue of employing the SMPLON signal 736, power to the DAQ board can be turned on and off on a need basis when information has to be transferred to/from the DAQ board. Thus, upon determining a need to power up the DAQ board, the main processor 602 can activate the SMPLON signal 736, which in turn drives and turns on the transistor 829. By virtue of driving the transistor 829, the voltage at the reference point 824 drives a voltage regulator 830, which outputs a 5 volt power supply via interconnect 832 to a DAQ connector 834. The DAQ connector 834 is connected to the DAQ board. A plurality of additional communication links 836 are additionally connected to the DAQ connector 834 via feedthrough caps 838 on a shielding box (represented by dashed lines) 840.

As indicated above, the power to the hand-held device 300 itself can be turned on/off by utilizing (e.g., pressing) the power switch 388 to activate the PWRSW signal 738. Upon activating the PWRSW signal 738 (by pressing the power switch 388), the transistor 820 is turned on, thereby providing a voltage at the reference point 824 (either from the battery 734 or alternatively directly from an external source). The voltage at the reference point 824, as indicated above, is then employed to drive the voltage regulator 826, which provides a 5 volt power supply to power various components of the hand-held device 300. In addition to driving the transistor 820, the PWRSW signal 738 turns on transistor 842, which serves to hold the power switch signal down. By virtue of the PWRSW signal 738 driving the transistor 842, the hand-held device continues to be powered on after releasing the power switch. To turn the hand-held device 300 off, the power switch can be pressed again, which turns the transistors 820 and 842 off, thereby cutting off the power supply to the various components of the hand-held device.

In addition to the aforementioned components, the power section 658 also includes a pair of connectors 844 and 846, one of which serves as a plug and the other as a receptacle to provide the plurality of communication signals 836 to a programmer for programming the hand-held device 300 and, more particularly, the main processor 602. Furthermore, similar to the main board circuit 600, certain of the components of the power section 658 are shielded within a shielding box 848 (represented by dashed lines). Communication between components inside the shielding box 848 and those outside the shielding box is facilitated through feed through capacitors 850.

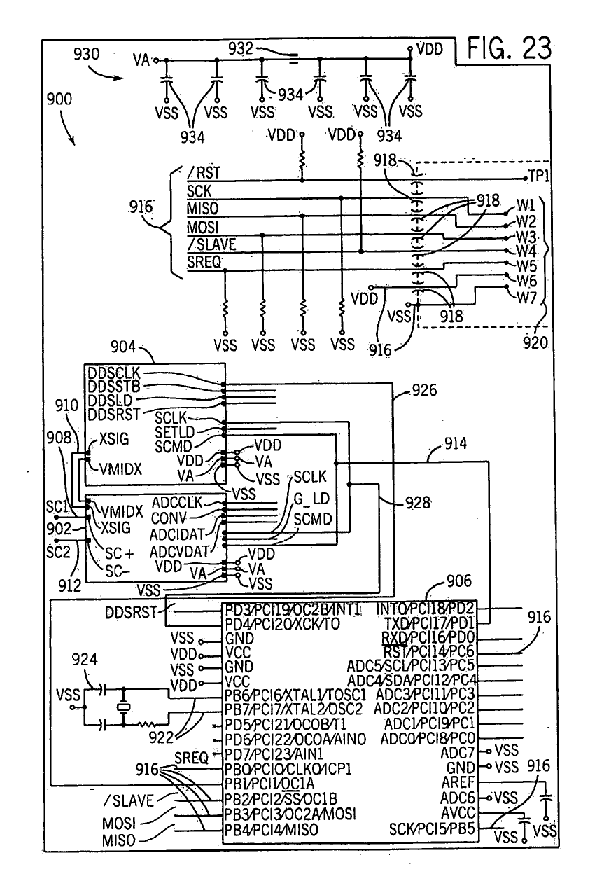

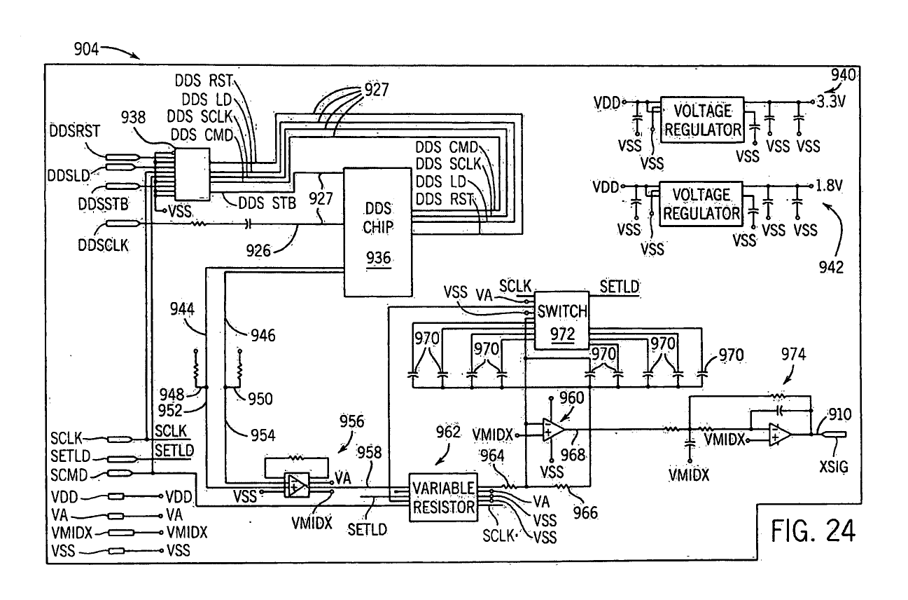

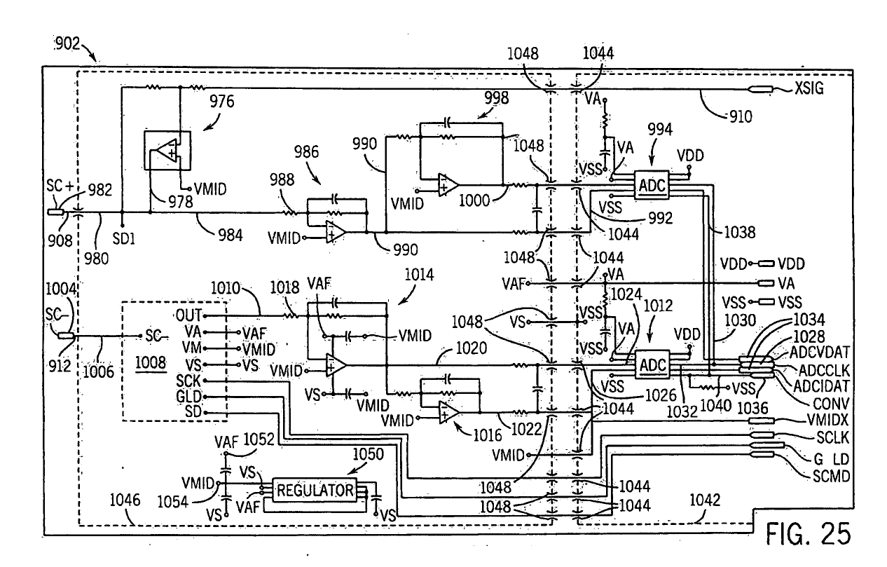

Referring now to FIG. 23, a Data Acquisition Board (DAQ) circuit 900 representative of the DAQ board 310 is shown in greater detail, in accordance with at least some embodiments of the present invention. As shown, the DAQ circuit 900 includes a transimpedance & power amplifier (TPA) block 902 and a signal generator 904, both of which are operating under control of a DAQ processor 906. The TPA block 902 generates and measures an alternate current (AC) voltage excitation signal provided along excitation voltage line 908 by employing an XSIG signal on XSIG line 910 generated by the signal generator block 904. The excitation voltage along the excitation voltage line 908 is used for exciting the sample cell electrodes 344 (see FIG. 18) of the sample cell to generate a resultant AC current signal, which is received along AC current line 912 and measured by the TPA block 902. Information from the TPA block 902 is then communicated to the DAQ processor 906, which in turn communicates that information to the main processor 602 (see FIG. 21). The main processor 602 (see FIG. 21) determines the biodiesel blend percentage and other properties of biodiesel in the sample fluid, in a manner described above. Details about the TPA block 902 and the signal generator block 904, respectively, are discussed below in regards to FIGS. 25 and 24, respectively.

Further, as indicated above, the operation of the TPA block 902 and the signal generator block 904 is controlled by the DAQ processor 906. In general, the DAQ processor 906 is a communication device that conveys information measured by the DAQ circuit 900 to the main board circuit 600 (see FIG. 21) and more particularly, to the main processor 602, as described below. In addition, the DAQ processor 906 serves as a set-up device that determines various parameters including, for example, amplifier gains, capacitor values, Direct Digital Synthesis (DDS) chip values etc. to generate desired frequency levels and other parameters employed by the TPA and the signal generator blocks for generating and measuring the excitation voltage signal (on excitation voltage line 908) and the resultant current signal (on AC current line 912). The function of the DAQ processor 906 as a set-up device is described in greater detail below. The set-up parameters from the DAQ processor 906 are communicated to each of the TPA and the signal generator blocks 902 and 904, respectively, via a communication line 914, which in at least some embodiments is a bi-directional communication link also conveying measurement information from the TPA and the signal generator blocks to the DAQ processor. Notwithstanding the fact that a single communication line 914 for conveying information between the DAQ processor 906 and the TPA and the signal generator blocks 902 and 904, respectively, is shown, it will be understood that various other set-up, processing and other signals and parameters can be conveyed between those blocks by way of the other signal connections present on those blocks.

Additionally, as indicated above, the DAQ processor 906 is capable of communicating with the main processors 602 (see FIG. 21) of the hand-held device 400 (see FIG. 19). Typically, the communication between the DAQ processor 902 and the main processor 602 is facilitated via interconnects 916. In at least some embodiments, the interconnects 916 can include signals such as, power signals VDD and VSS, and serial communication signals MISO, MOSI, SREQ, SCK, /RST and/SLAVE. In other embodiments, other types of power and communication signals and other signals for establishing proper transfer of information between the DAQ processor 906 and the main processor 602 can be present as well. Particularly, information from the DAQ processor 906 is conveyed along the interconnects 916 and through a plurality of ferrite beads (or filters) 918 and pads 920 (which in at least some embodiments can be the pads 348 in FIG. 18) to the main processor 602 on the main board 600. Information from the main processor 602 can similarly be communicated via the pads 920, the ferrite beads 918 and the interconnects 916 to the DAQ processor 906. It should be noted that for clarity of expression, the interconnects 916 are shown separate from the DAQ processor 906. However, it will be understood to one of skill in the art that the interconnects 916 are connection points on the DAQ processor 906 (e.g., as shown on the DAQ board 310 in FIG. 18) itself that connect to the pads 920 via the ferrite beads 918. Further, notwithstanding the fact that communication between the DAQ processor 906 and the main processor 602 has been described above, it will be understood that a similar communication channel between the DAQ processor and other components of the hand-held device 400 can be established as well.

Further, the operation of the DAQ processor 906 is driven by a clock signal provided along clock line 922, generated by a crystal oscillator 924. In at least some embodiments of the present invention, the crystal oscillator 924 has a frequency of 18.432 MHz, although other frequency crystal oscillators for generating the clock signal 922 can be employed as well in other embodiments. The clock signal (along clock line 922) generated by the crystal oscillator 924 is additionally provided through the DAQ processor 906 to the signal generator block 904 as a DDS clock (DDSCLK) along DDSCLK line 926 for driving an additional component described below. A serial data clock signal (SCLK) along SCLK line 928 is also conveyed to each of the TPA and the signal generator blocks 902 and 904, respectively, for synchronizing transfer of data and various input/output operations.

In at least some embodiments, the DAQ processor 906 can be an 8-bit ATmega328P processor available from the ATMEL Company of San Jose, Calif. In other embodiments, other processors including for example, ATmega168P, ATmega88P, and the like from the ATMEL company can be employed. In alternate embodiments, processors other than those mentioned above, including processors from companies other than ATMEL, can be used depending particularly upon the speed, number of input/output ports, memory and packaging size of that processor.

The DAQ circuit 900 further includes a circuit component 930 having a ferrite bead 932 and a plurality of capacitors 934. In general, the ferrite bead 932 is a passive electric component employed for suppressing noise within the various components of the DAQ circuit 900. Particularly, the combination of the ferrite bead 932 and a plurality of capacitors 934 can be employed for filtering or blocking switching transients that show up on digital circuit power lines, thereby minimizing noise within the circuit 900. Notwithstanding the fact that in the present embodiment, the circuit component 930 is illustrated as a stand alone component, it will be understood by a person of skill in the art that the circuit component is in fact integrated into one or more components of the DAQ circuit 900 for filtering noise in those components.

Referring now to FIG. 24, an exemplary circuit diagram of the signal generator 904 is shown, in accordance with at least some embodiments of the present invention. As indicated above, the signal generator 904 generates the XSIG signal (along XSIG line 910), which is employed by the TPA block 902 (see FIG. 23) to generate the excitation voltage signal along the excitation voltage line 908 (see FIG. 23). Typically, the signal generator 904 employs a plurality of power and clock signals including signals that communicate the various parameters set by the DAQ processor 906, described above, to generate the XSIG signal. Particularly, the generation of the XSIG signal begins by virtue of utilizing a DDS chip 936 that creates an analog sine wave current signal, which is then converted into a voltage signal and passed through one or more filter elements to generate the XSIG signal.

With respect to the DDS chip 936 in particular, it is a 14-bit Digital-to-Analog Converter (DAC) capable of generating analog sinusoidal current waveforms at various frequencies (e.g., 1 MHz-400 MHz) from digital signals. In at least some embodiments, the DDS chip 936 can be an AD9951 DDS chip from the Analog Devices, Inc. Company of Norwood, Mass. In other embodiments, other types of direct digital synthesizers capable of accepting digital signals and generating analog waveforms therefrom at various frequencies can be employed as well. Further as shown, the input to the DDS chip 936 is the DDSCLK signal along the DDSCCLK line 926, as well as DDS inputs 927, each of which is provided by the DAQ processor 906 along with various other set-up and processing parameters.

Additionally, to enable communication between devices of varying voltage levels, the signals 927 from the DAQ processor 906 are routed to the DDS chip via a voltage translator device 938. In at least some embodiments, the voltage translator device 938 can be a high speed TTL-compatible FET bus switch such as an SN74CB3T3245 level shifter available from the Texas Instruments Company of Dallas, Tex., although other types of voltage translators that are commonly available and frequently employed can be used as well. The voltage translator device 938 receives signals from the DAQ processor 906, which operates at a 5 volt power supply and converts the voltage level of (e.g., level shift) those signals for receipt by the DDS chip 936, which operates at a 3.3 volt power supply. thus, by virtue of providing the voltage translator device 938, the DAQ processor 906 can communicate safely with the DDS chip 936.

In addition to the voltage translator device 938, the signal generator 904 additionally includes a pair of voltage regulators 940 and 942 for enabling communication between devices of varying voltages. Generally speaking, the voltage regulators 940 and 942 are electrical devices that are employed for regulating and/or maintaining one or more of AC and/or DC voltage levels in a system. For example, the voltage regulator 940 takes in a 5 volt digital power supply (VDD) to generate a 3.3 volt power supply for powering the digital portion of the DDS chip 936. Relatedly, the voltage regulator 942 takes as input an analog 5 volt voltage to generate an output analog voltage of 1.8 volts that can be employed for operating the analog portion of the DDS chip 936. Notwithstanding the fact that the voltage translator device 938 and the voltage regulators 940 and 942 have been described with reference to the DDS chip 936, a person skilled in the art will appreciate that the stepped down output voltages generated by those devices can be employed by other devices as well that operate on the lower digital and analog voltage levels generated by the voltage translator device 938 and the voltage regulators 940 and 942. Further, although the voltage regulators 940 and 942 have been shown as stand-alone components it will be understood that these devices are in fact connected in operational association to the DDS chip 936 and/or other components employing the stepped down voltages generated by these voltage regulators.

Thus, power, set-up and other digital signals from the DAQ processor 906 are input into the DDS chip 936 via the voltage translator device 938 and the voltage regulators 940 and 942. Upon receiving the input signals 926 and 927, the DDS chip 936 generates a pair of step-wise analog sine waveforms of current signals along current lines 944 and 946. The resulting current signals along current lines 944 and 946 are then converted by way of respective load resistors 948 and 950 into a pair of voltage values output along voltage lines 952 and 954. Subsequent to conversion, the pair of voltage values (along voltage lines 952 and 954) is input as a differential voltage into a differential amplifier 956. Within the differential amplifier 956, the input differential voltage (e.g., difference between the two input voltage values on voltage lines 952 and 954) is converted into a unipolar voltage signal that is transmitted through the differential amplifier along a unipolar voltage line 958. In at least some embodiments, the differential amplifier 956 can be an AD623 differential amplifier available from the Analog Devices Company. In other embodiments, any of a variety of commonly available and frequently used off-the-shelf differential amplifiers can potentially be employed.

The unipolar voltage line 958 from the differential amplifier 956 is fed into an operational amplifier (op-amp) 960 via an electronic chip 962. In particular, the op-amp 960 is designed to be an inverting amplifier with values of input resistance 964 and feedback resistance 966 chosen such that the gain of the op-amp is negative one (−1). Notwithstanding the specific parameters (e.g., the input resistance 964 and the feedback resistance 966) of the op-amp 960, the gain of the op-amp 960 can be fine-tuned by varying the input resistance 964 with respect to the feedback resistance 966 of the op-amp, such that the resulting XSIG signal (on XSIG line 910) is reasonably close to a peak voltage, which in at least some embodiments can be 750 millivolts (mV). Nevertheless, in other embodiments, the peak voltage of the XSIG signal (along XSIG line 910) can vary depending particularly upon the material of the sample fluid being tested. Typically, the gain of the op-amp 960 can be fine-tuned by feeding the unipolar voltage line 958 into the op-amp via the electronic chip 962.

The electronic chip 962 serves as a variable resistor in which the value of the input resistance 964 can be varied in a well known manner. The operation of the electronic chip 962 is controlled by the DAQ processor 906 (see FIG. 23), which can set a specific value (e.g., up to 100 KΩ down to 0Ω) for the input resistance 964 to modify the gain of the op-amp 960. Thus, by virtue of controlling the input resistance 964, the gain (feedback resistance/input resistance) of the op-amp 960 can be controlled (e.g., fine-tuned). In other embodiments, other methods of varying the gain of the op-amp 960 can be employed as well. In at least some embodiments, the electronic chip 962 can be an AD5161 256-Position SPI/I²C Selectable Digital Potentiometer available from the Analog Devices Company, although in other embodiments other types of electronic devices capable of serving as a variable resistor can be employed.

Furthermore, each of the output current signals along current lines 944 and 946 generated by the DDS chip 936 is a step signal composed of a plurality of minute current steps (or noise), which are translated into voltage steps upon conversion by the load resistors 948 and 950 into the voltage values along voltage lines 952 and 954. The stepped nature of the voltage values (on voltage lines 952 and 954) is passed along to an output line 968 of the op-amp 960. To minimize (or even completely eliminate) the steps in the output line 968, one or more filters, described below, can be utilized. For example, capacitors connected to the feedback resistance 966 can serve as a filter and, more particularly, a single pole, low pass filter for removing noise in the unipolar voltage signal on the unipolar voltage line 958. However, given that the excitation voltage signal on the excitation voltage line 908 is generated for a broad range of frequencies, a capacitance value for one frequency may not necessarily work for another frequency value. Thus, the capacitance across the feedback resistance 966 is varied for obtaining a relatively smooth output signal (on the output line 968) for each of the frequency values.

Typically, the capacitance across the feedback resistance 966 can be varied by selecting one of a plurality of capacitance values 970 via an electronic switch 972 operated under control of the DAQ processor 906. In at least some embodiments, the electronic switch 972 can be a MAX349CAP serially controlled multiplexer available from the Maxim Integrated Products Company of Sunnyvale Calif. In other embodiments, other types of electronic switches or electronic components capable of selecting one of the plurality of capacitance values 970 can be employed. Thus, by virtue of controlling the input resistance 964 and the capacitance value 970 across the feedback resistance 966, the resulting output voltage signal on output line 968 of the op-amp 960 can have a relatively smoother waveform closer to the peak value (e.g., 750 mV).

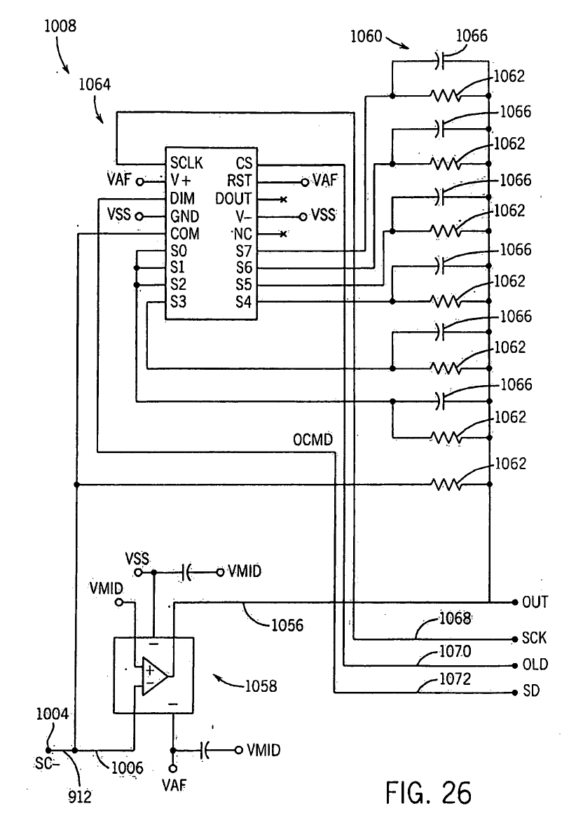

The output voltage along output line 968 is then input into a second filter 974 for removing any residual noise in the output voltage to generate a smooth AC voltage signal. In at least some embodiments, the second filter 974 is a two pole, low pass filter, such as, the AD8606AR low noise input/output operational amplifier available from the Analog Devices Company. The output signal generated by the second filter 974 is the XSIG signal transmitted on the XSIG line 910. Thus, the signal generator 904 upon receiving instruction from the DAQ processor 906 generates the XSIG signal that is employed by the TPA block 902 to further generate the excitation voltage signal, as explained in greater detail with respect to FIGS. 25 and 26, below.

Turning now to FIG. 25, the TPA block 902 is shown in greater detail, in accordance with at least some embodiments of the present embodiment. As shown, the XSIG signal on the XSIG line 926 generated by the signal generator 904 discussed above, is input into and measured by, the TPA block 902, for generating the excitation voltage signal on excitation voltage line 908. Particularly, the XSIG signal from the signal generator 904 is fed into a first op-amp device 976 set up as an inverting op-amp with a gain of negative one (−1) to provide a buffered XSIG line 978. The buffered XSIG line 978 is then sent out as the excitation voltage line 908 along interconnect link 980 and pad 982. Additionally, the buffered XSIG line 978 is fed via an interconnect 984 into a second op-amp device 986 which, similar to the op-amp device 976, is an inverting operational amplifier with a gain of −1. The voltage at the buffered XSIG line 978 is measured at an input resistance 988 of the second op-amp device 986 and buffered and inverted to generate an output line 990. The output line 990 is employed for driving a negative input 992 of an analog-to-digital converter (ADC) device 994. Additionally, the output voltage line 990 is used for driving (e.g., via communication link 996) another stage of an identical op-amp device 998, which buffers and inverts the output voltage 990 to generate an output line 1000 that drives a non-inverting input 1002 of the ADC device 994. Thus, two signals (i.e. differential signals), which are 180 degrees out of phase are input into the ADC device 994 as the non-inverting and inverting inputs 1002 and 992, respectively.

In at least some embodiments the op-amp device 976 can be an AD8605 op-amp device available from the Analog Devices Company (similar to the AD8606AR device). Relatedly, the op-amp devices 986 and 998, in at least some embodiments, can be the AD8606AR device also available from the Analog Devices Company and described above. Notwithstanding the particular devices indicated above for each of the op-amp devices 976, 986 and 998, it is an intention of this invention to include embodiments employing other commonly available and frequently used devices capable of providing functionality similar to the op-amp devices above.

Referring still to FIG. 25, the current line 912 generated within the sample cell in response to the excitation voltage line 908 is received into the TPA block 902 via pad 1004 and interconnect 1006 and fed into a transimpedance amplifier (TIA) module 1008. The TIA module 1008 in particular converts the current signal on current line 912 into a voltage signal for measurement, as described in more detail below with regards to FIG. 26. An output voltage along voltage line 1010 of the TIA module 1008 is then measured and converted into a differential signal, which is employed for driving a second ADC device 1012. Similar to the conversion of the buffered XSIG line 978, the voltage on the voltage line 1010 can be converted into a differential signal by way of employing two stages of op-amp devices namely, a first op-amp device 1014 and a second op-amp device 1016. In addition to being converted into a differential signal, the voltage signal on voltage line 1010 is measured at an input resistance 1018 of the first op-amp device 1014. Each of the op-amp devices 1014 and 1016 serve as buffers that generate outputs 1020 and 1022, respectively, which drive respective non-inverting and inverting inputs 1024 and 1026 of the ADC device 1012.

With respect to the ADC devices 994 and 1012 in particular, each of those devices is an 18-bit analog-to digital converter connected together in a daisy-chain fashion. In particular, each of the devices 994 and 1012 accepts analog differential signals (e.g., the ADC device 994 receives differential of the non-inverting inputs 992 and 1002, and the ADC device 1012 receives differential of the non-inverting inputs 1024 and 1026) to generate a digital output. Typically, the operation of the ADC 994 and 1012 is synchronized by an ADC clock (ADCCLK) 1028 generated by the DAQ processor 906. As shown, the ADCCLK 1028 is provided to both the ADC devices 994 and 1012 via interconnect links 1030 and 1032, respectively, to clock out data (ADC/DAT and ADCVDAT) 1034. Also provided as input to both the ADC device 994 and the ADC device 1012, is a convert signal, CONV 1036. Similar to the ADCCLK 1028, the CONV 1036 is generated by the DAQ processor 906 and communicated to each of the ADC devices 994 and 1012 via interconnects 1038 and 1040, respectively.

Generally speaking, the CONV 1036 governs and controls the operations of both the ADC devices 994 and 1012, thereby serving multiple purposes. For example, the CONV 1036 initiates the analog-to-digital conversions performed at specific times for each of the various frequencies for which measurements are taken. By virtue of controlling the conversion of the signals, multiple discrete readings (e.g., 10 readings each of current and voltage) can be obtained for a single AC cycle. Additionally, the CONV 1036 controls the timing of the ADCJDAT and ADCVDAT data 1034 from the ADC devices 994 and 1012. Thus, the CONV 1036 synchronizes the conversions (e.g., analog-to-digital), while controlling the process of outputting the digital ADCDAT 1034. Further, as indicated above, the output ADC/DAT and ADCVDAT data 1034 is then provided to the DAQ processor 906, which in turn provides that signal to the main processor 602 (see FIG. 21) for computing impedance and determining biodiesel FAME percentage in a manner described above. In at least some embodiments, each of the ADC devices 994 and 1012 is an AD7690 device available from the Analog Devices Company. In other embodiments, other analog-to-digital converters capable of providing the functionality described above, can be used as well.

Furthermore, in at least some embodiments, and as shown, the ADC devices 994 and 1012 are enclosed within a box (represented by dashed lines) 1042. In particular, the box 1042 is a metal box and, more particularly, a shielding box, five sides of which are soldered down onto a printed circuit board (PCB) of the hand-held device 400, and the sixth side of which represents a bottom layer of copper on the PCB. Additionally, the shielding box 1042 is designed such that any signals going out and coming into the shielding box are passed through feed through capacitors 1044, each of which is a three terminal device having center (e.g., ground), input and output points. Further, the feed through capacitors 1044 are designed such that any signals passing through the shielding box 1042 (e.g., via the feed through capacitors) pass through a small capacitance value to minimize the impact of RF on the circuitry within the box.

A similar shielding box 1046 having a plurality of feed through capacitors 1048 is provided around the op-amp devices 976, 986, 998, 1014, and 1016, and the TIA module 1008. Typically, signals passing from the components within the box 1046 first pass through the feed-through capacitors 1048 (e.g., while exiting the box 1046) and then through the feed-through capacitors 1044 (e.g., while entering the box 1042) to components within the box 1042. Relatedly, signals pass through the feed-through capacitors 1042 and then through the feed-through capacitors 1048 upon passing from the box 1042 to the box 1046.

Also provided within the shielding box 1046 is a rail splitter chip 1050. The rail splitter chip 1050 takes in a 5 volt signal 1052 to create a VMID voltage signal 1054 representing a midpoint of the voltage supply. Generally speaking, by virtue of employing the rail splitter chip 1050, various electronic components of the TPA block 902 can employ a larger voltage signal to be subdivided into a digital value, thereby additionally minimizing the effects of noise in those signals. In at least some embodiments, the rail splitter chip 1050 can be a TLE2426 rail splitter chip available from the Texas Instruments Company of Dallas, Tex. In other embodiments, other types of rail splitters commonly available and frequently employed can be utilized as well.

Referring now to FIG. 26 in conjunction with FIG. 25, an exemplary circuit diagram of the TIA module 1008 is shown, in accordance with at least some embodiments of the present invention. Generally speaking, the TIA module 1008 receives the resulting current line 912 from the sample cell via the pad 1004 and the interconnect 1006 and converts the current signal on that line into a voltage signal for measurement. In particular, for converting the current signal along the current line 912 into a voltage signal transmitted along a resulting voltage line 1056, the current signal is input into an op-amp device 1058. The resulting voltage line 1056 is then output to the TPA block 902 for measurement (e.g., the amplitude and phase of the current signal being measured relative to the amplitude and phase of the excitation signal), in a manner described above.

Furthermore, given that a wide range of currents for a wide range of excitation voltages and frequencies are measured, the value of a feedback resistance 1060 (which facilitates the current to voltage conversion) associated with the op-amp 1058 is varied for an accurate current- to-voltage conversion. In at least some embodiments of the present invention, one of a plurality of resistance values 1062 can be selected to serve as the feedback resistance 1060. Furthermore, each one of the resistance values 1062 is designed to represent roughly a decade of current range. Specifically, in at least some embodiments, the resistance values 1062 can increase by decades (e.g., 100Ω, 1 KΩ, 10 KΩ and the like), with those values corresponding to the decade of current ranging from 10 milliAmp to 10 nanoAmp.

Typically, an electronic switch 1064 can be employed for selecting one of the plurality of resistance values 1062. In at least some embodiments, the electronic switch 1064 can have 8 switches to which the resistance values 1062 can be connected in a manner that reduces leakage from the input to the output of the electronic switch. For example, the low end of resistance value of 100 Ohm can be connected to 3 switches together to reduce the effective resistance for minimizing leakage. Relatedly, the higher end value of 100 MΩ employed for measuring the lowest current can be wired directly to the op-amp device 1058 to create a voltage at the output and also to minimize leakage at the electronic switch 1064. In at least some embodiments, the electronic switch 1064 can be a MAX349 multiplexer from the Maxim Integrated Products Company, described above. In other embodiments, other electronic switch devices can be employed as well. Further, each of the resistance values 1062 has a small capacitor 1066 associated with it. The capacitor 1066, in general, is a small capacitor having an impedance value that is dominated by the impedance value of its respective resistor. The combination of each of the resistors and capacitor forms a filter element added for stability of the op-amp device 1058.

The selection of one of the plurality of resistance values 1062 to serve as the feedback resistance 1060 is performed by the electronic switch 1064 under control of the DAQ processor 906. In particular, the DAQ processor 906 performs an auto-gain process in which the best resistor for each current signal 912 is selected such that the current signal is as large as possible without hitting the rails. The auto-gain process is a well known process and is therefore not described here in detail for conciseness of expression. The auto-gain process is typically performed for each frequency value for which measurements are taken. Particularly, the DAQ processor 906 has programmed therein a look-up table having a sequence defining a particular analysis to be performed on each frequency. More particularly, the sequence defining the analysis includes a first number representing a frequency and a second number representing the number of measurement cycles for that frequency. Furthermore, for each cycle of each frequency, each AC waveform can be sampled, for example, at 10 equally spaced points.

Thus, the look-up table serves several purposes. First, the auto-gain process is performed, which is an algorithmic process of consulting the look-up table for a specific frequency value, and sampling the waveform several times to determine the largest resistance values 1062 to be employed for the feedback resistance 1060. The chosen value is then conveyed to the TIA module 1008, as described below. Additionally, the number of cycles corresponding to the selected frequency (e.g., for which the auto-gain process is performed) is looked-up from the look-up table. Typically, in each cycle, 10 discrete sample points are collected for each of current and voltage, resulting in 20 discrete values in each cycle. The cycle is repeated multiple times (e.g., twice) for each chosen frequency value. Further, all of the above information for each frequency, namely, the sequence numbers representing the frequency value and the number of cycles, and the other information describing how the information is collected is compiled in a singular packet and sent off to the main processor 314 for processing. The aforementioned analysis steps are then repeated for multiple frequency values (e.g., 7 different frequency values).

Thus, upon setting a specific resistor value by the DAQ processor 906, that value is communicated to the electronic switch 1064 via three leads, namely, an S-clock (SCK) 1068, a G-load (GLD) 1070 and a serial data (SD) 1072. Particularly, the SCK 1068, the GLD 1070 and the SD 1072 are standard connections to the electronic switch 1064 for controlling the opening and closing of the various switches. Typically, pulses are sent by the DAQ processor 906 (e.g., in the form of parameters set by the DAQ processor) to the electronic switch 1064, which governs the operation of the electronic switch, and in particular, selection of one of the plurality of resistance values 1062 to serve as the feedback resistance 1060. Upon selecting the value of the feedback resistance 1060, the output voltage line 1056 is generated representing a voltage relative to the current signal on current line 912. The output signal 1056 is then passed onto the TPA block 902 for measurement, as described above.

Notwithstanding the various embodiments of the hand-held device 300, and the various electronic device components described above with respect to FIGS. 1-26, various additions and/or refinements to the device are contemplated and considered within the scope of the present invention. For example, although the main board circuit 600, the power section circuit 726, and the various components of the DAQ circuit 900 including the circuit diagram of the signal generator block 904. The TPA and the TIA blocks 902 and 1008, respectively, have been explained with respect to specific functionality, it can be appreciated that those circuits are capable of performing a wide variety of additional operations other than those described above. Similarly, although the main processor 602 has been explained with respect to specific functionality, it can be appreciated that those processors are capable of performing a wide variety of additional operations other than those described above. Further, the type, model and specifications of the various components of the hand-held device can vary from one embodiment to another. Additionally, the communication interfaces and connections with respect to the various components described above are exemplary and as such, variations are contemplated and considered within the scope of the present invention.

Conventional components other than described above that are commonly employed in electronic systems are contemplated and can be used in conjunction with the hand-held device 300. Further, any values of the various electronic components (e.g., values of capacitors and resistors) that are shown in the drawings, are merely exemplary. It will be understood to a person of art that such values can in fact be modified as desired, depending particularly upon the embodiment and the type of the sample fluid being tested. In other embodiments, values other than those mentioned can potentially be employed as well.

Further, despite any method(s) being outlined in a step-by-step sequence, the completion of acts or steps in a particular chronological order is not mandatory. Any modification, rearrangement, combination, reordering, or the like, of acts or steps is contemplated and considered within the scope of the description and claims.

It is specifically intended that the present invention not be limited to the embodiments and illustrations contained herein, but include modified forms of those embodiments including portions of the embodiments and combinations of elements of different embodiments.

The following United States patent documents are hereby incorporated by reference in their entirety herein. U.S. Pat. No. 6,278,281; U.S. Pat. No. 6,377,052; U.S. Pat. No. 6,380,746; U.S. Pat. No. 6,839,620; U.S. Pat. No. 6,844,745; U.S. Pat. No. 6,850,865; U.S. Pat. No. 6,989,680; U.S. Pat. No. 7,043,372; U.S. Pat. No. 7,049,831; U.S. Pat. No. 7,078,910; U.S. Patent Appl. No. 2005/0110503; and U.S. Patent Appl. No. 2006/0214671.

Although the invention has been described in detail with reference to preferred embodiments, variations and modifications exist within the scope and spirit of the invention as described and defined in the following claims.

What is claimed is:

1. A hand-held impedance spectroscopy analysis device for analyzing fluids wherein the impedance spectroscopy device is in communication with a sample cell including a reservoir containing a fluid sample, the sample cell including a sample cell circuit and two metal plates in contact with the fluid sample and in contact with a pair of electrodes, the analysis device comprising:
a processing system including a main processor which is responsive to commands from a user input device,
a data acquisition circuit which receives power and command signals from the processing system, and is operable to transmit excitation signals to the electrodes, wherein the excitation signals are applied at each frequency in a predetermined set of frequencies, the data acquisition circuit further operable to receive response signals from the electrodes indicative of the fluid sample at each frequency in the predetermined set of frequencies and to convert the response signals into a magnitude and phase angle data set, and
wherein the main processor is operable to receive the magnitude and phase angle data set from the data acquisition circuit and perform an impedance spectroscopy algorithm using the magnitude and phase angle data set to determine a fluid property.

2. The analysis device of claim 1 wherein the main processor is operable to control power to the sample cell circuit.

3. The analysis device of claim 1 wherein the main processor is operable to receive at least one of calibration information and temperature information from the sample cell circuit, and the impedance spectroscopy algorithm uses the magnitude and phase angle data set and the information from the sample cell circuit to determine a fluid property.

4. The analysis device of claim 1, wherein the processing system is operable to perform at least one of the functions in the group including communicating the determined fluid property to a display device or a printer, operating in a battery mode, and transmitting commands to the sample cell circuit.

5. The analysis device of claim 1, wherein the processing system further includes a plurality of contacts for establishing a connection with an external power source, a circuit for providing a signal indicating the presence of an external power source, and wherein when the main processor receives the signal indicating the presence of an external power source, the main processor is powered by the external power source.

6. The analysis device of claim 1, wherein the processing system further includes a printer interface, and the main processor is operable to control information sent to the printer interface.

7. The analysis device of claim 1, further including a real time clock and calendar device for keeping track of current time and date and which is controlled by the main processor.

8. The analysis device of claim 7, wherein the real time clock and calendar device includes an oscillator, and the processing system further includes a capacitor to provide power to the real time clock and calendar device in the event of power interruption.

9. The analysis device of claim 1, wherein the processing system is responsive to a power key to turn the main processor on and off.

10. The analysis device of claim 1, wherein the processing system further includes a reset chip for resetting a display device upon start-up.

11. The analysis device of claim 1, further including a power section for receiving a light source intensity control signal from the main processor for controlling the intensity of a light source in a display device.

12. The processing system of claim 1, further including a power section operable to receive a power on signal from the main processor for controlling power to the data acquisition circuit.

13. The processing system of claim 12, further including a shielding box surrounding the power section and main processor.
